(19) United States
(12) Patent Application Publication
(10) Pub. No.: US 2026/0056629 A1
(43) Pub. Date: Feb. 26, 2026

(54) Display Device

(71) Applicant: LG Display Co., Ltd., Seoul (KR)

(72) Inventors: Hyangmyoung Gwon, Paju-si (KR); JiHyun Jung, Paju-si (KR); JaeGyun Lee, Paju-si (KR); Ruda Rhe, Paju-si (KR)

(21) Appl. No.: 19/247,775

(22) Filed: Jun. 24, 2025

(30) Foreign Application Priority Data
Aug. 22, 2024 (KR) 10-2024-0112688

(51) Int. Cl. G06F 3/041; H10K 59/123; H10K 59/131; H10K 59/40

(52) U.S. Cl. CPC G06F 3/04164; H10K 59/123; H10K 59/131; H10K 59/40

(57) ABSTRACT

A display device including a substrate, touch electrodes on the substrate and located in the display area, touch pads on the substrate and located in the non-display area, and touch routing lines on the substrate, electrically interconnecting the touch electrodes and the touch pads, and in a portion of an outer edge of the display area. The touch routing lines may include a first touch routing line for electrically connecting a first touch electrode to a first touch pad, and an n^{th} touch routing line for electrically connecting an n^{th} touch electrode to an n^{th} touch pad. The first touch routing line may include a first single line portion and a first double line portion, which are electrically connected to each other, and the first single line portion may be electrically connected to the first touch electrode through the first double line portion.

### CROSS REFERENCE TO RELATED APPLICATION

This application claims priority benefit from the Republic of Korea Patent Application No. 10-2024-0112688, filed on Aug. 22, 2024, which is hereby incorporated by reference in its entirety.

### TECHNICAL FIELD

The present disclosure relates to electronic devices, and more specifically, for example, without limitation, to display devices.

### BACKGROUND

In today's society, display devices are widely used and increasingly important for presenting images or visual information to users. As needs for providing a user-friendly environment increases, various functions are integrated into the display devices, and many of display devices tend to employ a touch-enabled input interface capable of receiving a touch-based input. Such touch display devices with the touch-enabled input interface allow users to input information or commands more intuitively and conveniently, compared with typical input devices, such as buttons, keyboards, mice, and the like.

These display devices may include a plurality of touch electrodes for touch sensing, and include a plurality of touch routing lines for connecting the plurality of touch electrodes to pads. The plurality of touch routing lines may be disposed in a non-display area of the display devices, and this configuration causes the size of the non-display area to increase.

### SUMMARY

To address this issue, one or more embodiments of the present disclosure may provide a display device including a touch routing line structure capable of reducing a size of a non-display area (bezel) in which a plurality of touch routing lines are disposed.

One or more embodiments of the present disclosure may provide a display device including a touch routing line structure capable of improving the quality of touch driving and touch sensing.

One or more embodiments of the present disclosure may provide a display device including a touch routing line structure capable of reducing coupling noise between touch channels.

One or more embodiments of the present disclosure may provide a display device including a touch routing line structure capable of reducing a difference in resistance between touch channels.

One or more embodiments of the present disclosure may provide a display device including touch routing lines disposed in a structure of being robust to display noise.

According to one or more example embodiments of the present disclosure, a display device can be provided that includes a substrate including a display area and a non-display area adjacent to the display area, n touch electrodes disposed on the substrate and located in the display area, where n is a natural number greater than or equal to 2, n touch pads disposed on the substrate and located in the non-display area, and n touch routing lines disposed on the substrate, electrically interconnecting the n touch electrodes and the n touch pads, and disposed in a portion of an outer edge of the display area. In one or more aspects, the n touch routing lines may include a first touch routing line for electrically connecting a first touch electrode among the n touch electrodes to a first touch pad among the n touch pads, and an nth touch routing line for electrically connecting an nth touch electrode among the n touch electrodes to an nth touch pad among the n touch pads. In one or more embodiments, in the display device, the first touch routing line may include a first single line portion and a first double line portion, which are electrically connected to each other, and the first single line portion may be electrically connected to the first touch electrode through the first double line portion.

According to one or more example embodiments of the present disclosure, a display device can be provided that includes a substrate including a display area and a non-display area adjacent to the display area, a common electrode disposed over the substrate and allowing a first common voltage for display driving to be applied, a signal line disposed on the substrate and delivering a signal different from the first common voltage, a plurality of touch electrodes located in the display area and disposed on the common electrode, and a plurality of touch routing lines electrically connected to the plurality of touch electrodes. In one or more aspects, the plurality of touch routing lines may include a first touch routing line including at least a portion not overlapping with the signal line, and an nth touch routing line overlapping with the signal line.

In one or more embodiments, in the display device, the common electrode may not extend under the at least a portion of the first touch routing line, but extend under the nth touch routing line.

According to one or more embodiments of the present disclosure, a display device may be provided that includes a touch routing line structure capable of reducing a size of a non-display area (bezel) in which a plurality of touch routing lines are disposed.

According to one or more embodiments of the present disclosure, a display device may be provided that includes a touch routing line structure capable of improving the quality of touch driving and touch sensing.

According to one or more embodiments of the present disclosure, a display device may be provided that includes a touch routing line structure capable of reducing coupling noise between touch channels.

According to one or more embodiments of the present disclosure, a display device may be provided that includes a touch routing line structure capable of reducing a difference in resistance between touch channels.

According to the one or more embodiments described herein, a display device may be provided that includes touch routing lines disposed in a structure of being robust to display noise.

According to the one or more embodiments described herein, a display device may be provided that is capable of reducing the size of a bezel of the display device, and thereby, capable of meeting size requirements on the design of the display device and helping the display device be lighter.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings.

FIG. 1 illustrates an example system configuration of a display device according to embodiments of the present disclosure;

FIG. 2 illustrates an example configuration of the display device according to embodiments of the present disclosure;

FIG. 3 is an example cross-sectional view of the display panel according to embodiments of the present disclosure;

FIG. 4 is an example plan view of the display panel according to embodiments of the present disclosure;

FIGS. 5 and 6 illustrate example touch sensor structures included in the display device according to embodiments of the present disclosure;

FIGS. 7 to 10 illustrate example touch routing line structures in the display panel according to embodiments of the present disclosure; and

FIGS. 11 to 14 illustrate example touch routing line structures in the display panel according to embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted or may be briefly discussed. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Any implementation described herein as an “example” is not necessarily to be construed as preferred or advantageous over other implementations.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other and may be variously inter-operated with each other and driven technically as those skilled in the art can sufficiently understand. Embodiments of the present disclosure may be carried out independently from each other or may be carried out together in co-dependent relationship.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

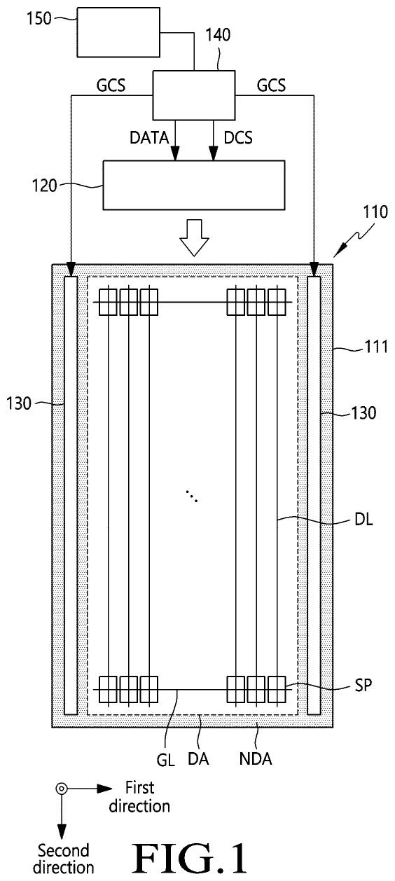

FIG. 1 illustrates an example system configuration of a display device 100 according to embodiments of the present disclosure. All components of each display device according to all aspects of the present disclosure are operatively coupled and configured.

Referring to FIG. 1, in one or more example embodiments, the display device 100 may include a display panel 110 and at least one display driving circuit, as elements for display images. The at least one display driving circuit may be one or more circuits for driving the display panel 110. For example, the at least one display driving circuit may include a data driving circuit 120, a gate driving circuit 130, a controller 140, and other circuit components, but embodiments of the present disclosure are not limited thereto.

The display panel 110 may include a substrate 111 and a plurality of subpixels SP disposed on the substrate 111.

The substrate 111 may include a display area DA and a non-display area NDA.

The display area DA may be an area allowing an image to be displayed, and also be referred to as an active area. A plurality of subpixels SP for image displaying may be disposed in the display area DA. The non-display area NDA may be an area where an image is not displayed, and be an area outside of the display area DA. The non-display area NDA may also be a non-active area, a bezel area, or a bezel. The non-display area NDA may include a pad area (which may be also referred to as a pad portion).

For example, the non-display area NDA may include a first non-display area adjacent to the display area DA, a second non-display area including the pad area, and a bending area between the first non-display area and the second non-display area.

At least one driving circuit may be connected or bonded to the pad area. As the bending area is bent, the bending area and the second non-display area may be located under the first non-display area and thus, be invisible in front of the display device 100. The first non-display area may have a very small size. However, aspects of the present disclosure are not limited thereto.

In one or more embodiments, when a user views the display device 100 in front thereof, all or most of the non-display area NDA may be invisible to the user, but embodiments of the present disclosure are not limited thereto.

In one or more embodiments, the display device 100 may be a self-emission display device in which light is emitted from the display panel 110 itself, but embodiments of the present disclosure are not limited thereto. In an example where the display device 100 is the self-emission display device, each of a plurality of subpixels SP included in the display panel 110 may include a light emitting element.

For example, the display device 100 according to embodiments of the present disclosure may be an organic light emitting display device in which light emitting elements are implemented using organic light emitting diodes (OLED). In another example, the display device 100 according to embodiments of the present disclosure may be an inorganic light emitting display device in which light emitting elements are implemented using inorganic material-based light emitting diodes. In another example, the display device 100 according to embodiments of the present disclosure may be a quantum dot display device in which light emitting elements are implemented using quantum dots, which are self-emission semiconductor crystals. In another example, the display device 100 according to embodiments of the present disclosure may be a micro LED display device, a mini LED display device, or the like.

The structure of each of a plurality of subpixels SP included in the display panel 110 may depend on types of display device 100. For example, in an example where the display device 100 is a self-emission display device including self-emission subpixels SP, each subpixel SP may include a self-emission light emitting element, one or more transistors, and one or more capacitors, but aspects of the present disclosure are not limited thereto.

Several types of signal lines for driving a plurality of subpixels SP may be disposed on the substrate 111 of the display panel 110. For example, the types of signal lines may include a plurality of data lines DL for delivering data signals (which may be referred to as data voltages or image signals) to a plurality of subpixels SP, a plurality of gate lines GL for delivering gate signals (which may be referred to as scan signals) to the plurality of subpixels SP, and the like.

For example, the plurality of data lines DL and the plurality of gate lines GL may intersect each other. Each of the plurality of gate lines GL may extend in a first direction (e.g., a row or column direction). Each of the plurality of data lines DL may extend in a second direction (e.g., the column or row direction) different from the first direction.

For example, the first direction may be the row direction, and the second direction may be the column direction. In another example, the first direction may be the column direction, and the second direction may be the row direction. Herein, the row direction and the column direction may not absolute directions, but relative directions. For example, the column direction may be the row direction and the row direction may be the column direction depending on a direction at which the display device 100 or the display panel 110 is viewed. Hereinafter, for convenience of explanation, discussions may be provided based on examples where each of a plurality of data lines DL is disposed in the column direction, and each of a plurality of gate lines GL is disposed in the row direction, but embodiments of the present disclosure are limited thereto. Herein, an angle between the first direction and the second direction may be vertical (or 90 degrees) or an angle different from the vertical.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

For example, the data driving circuit 120 may be connected to the display panel 110 by a tape-automated-bonding (TAB) technique or connected to a conductive pad such as a bonding pad of the display panel 110 by a chip-on-glass (COG) technique or a chip-on-panel (COP) technique or connected to the display panel 110 by a chip-on-film (COF) technique. However, aspects of the present disclosure are not limited thereto.

In one or more embodiments, the data driving circuit 120 may be located in, and/or electrically connected to, but not limited to, only one side or edge (e.g., an upper portion or a lower portion) of the display panel 110. In one or more embodiments, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area located outside of the display area DA of the display panel 110 or be disposed in the display area DA of the display panel 110.

The gate driving circuit 130 may be a circuit for driving a plurality of gate lines GL and can supply gate signals to the plurality of gate lines GL.

The gate driving circuit 130 can receive several types of gate driving control signals GCS, and a first gate voltage corresponding to a turn-on voltage (or a turn-on level voltage) and a second gate voltage corresponding to a turn-off voltage (or a turn-off level voltage). Thereby, the gate driving circuit 130 can generate a gate signal including a period with the first gate voltage and a period with the second gate voltage during a certain period of time (e.g., a period of one frame time or a sub-period of the period of one frame time), and supply the generated gate signals to the plurality of gate lines GL. For example, the turn-on level voltage may be a high level voltage and the turn-off level voltage may be a low level voltage. In another example, the turn-on level voltage may be a low level voltage and the turn-off level voltage may be a high level voltage.

In one or more embodiments, the gate driving circuit 130 included in the display device 100 may be embedded into the display panel 110 by a gate-in-panel (GIP) technique, but embodiments of the present disclosure are not limited thereto. In an example where the gate driving circuit 130 is implemented by the gate-in-panel (GIP) technique, the gate driving circuit 130 may be disposed on the substrate 111 of the display panel 110 during the process of manufacturing the display panel 110 or display device 100. Herein, the gate driving circuit 130 embedded in the display panel 110 by the gate-in-panel (GIP) technique may also be referred to as a “gate-in-panel circuit.”

For example, the gate driving circuit 130 may be disposed in the non-display area NDA of the display panel 110. In another example, the gate driving circuit 130 may be disposed in the display area DA of the display panel 110. In one or more embodiments, the gate driving circuit 130 may be disposed in, and/or electrically connected to, but not limited to, a first partial area (e.g., a left portion or a right portion) in the display area DA of the display panel 110. In one or more embodiments, the gate driving circuit 130 may be disposed in, and/or electrically connected to, but not limited to, a first partial area (e.g., a left portion or a right portion) in the display area DA, and a second partial area (e.g., the right portion or the left portion) in the display area DA. In one or more aspects, the gate driving circuit 130 may be disposed in all or one or more of areas of the display area DA.

In an example where the gate driving circuit 130 is disposed in the display area DA of the display panel 110, the gate driving circuit 130 may vertically overlap with one or more subpixels SP disposed in the display area DA. For example, the gate driving circuit 130 may vertically overlap with one or more light emitting elements and one or more transistors included in one or more subpixels SP disposed in the display area DA. The gate driving circuit 130 may vertically overlap with the plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially the same. In another example, the first semiconductor material and the second semiconductor material may be different from each other. For example, the first semiconductor material may be a silicon-based semiconductor material (e.g., a low temperature poly silicone (LTPS)), and the second semiconductor material may be an oxide semiconductor material. For example, the active layer may be a semiconductor layer, but aspects of the present disclosure are not limited thereto.

The controller 140 may be a device for controlling the data driving circuit 120 and the gate driving circuit 130, and can control driving timing for a plurality of data lines DL and driving timing for a plurality of gate lines GL.

The controller 140 can supply a data control signal DCS to the data driving circuit 120 to control the data driving circuit 120 and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, embodiments of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more embodiments, in addition to an image display function, the display device 100 can provide a touch sensing function of detecting the presence or absence of a touch by an object such as a finger, a pen, or the like, or a location of the touch.

In one or more aspects, the display device 100 may be a mobile terminal such as a smart phone, a tablet, or the like, or a monitor, a television (TV), or the like. Such devices may be of various types, sizes, and shapes. The display device 100 according to aspects of the present disclosure is not limited thereto. For example, the display device 100 may include displays of various types, sizes, and shapes for displaying information or images.

In one or more embodiments, the display device 100 may further include an electronic device such as a camera (e.g., an image sensor), an electronic unit or device such as a sensor capable of detecting an object, ambient light, etc., and the like. For example, the sensor may be a sensor capable of detecting an object or a human body by receiving light such as infrared light, ultrasonic light, ultraviolet light or the like. However, aspects of the present disclosure are not limited thereto.

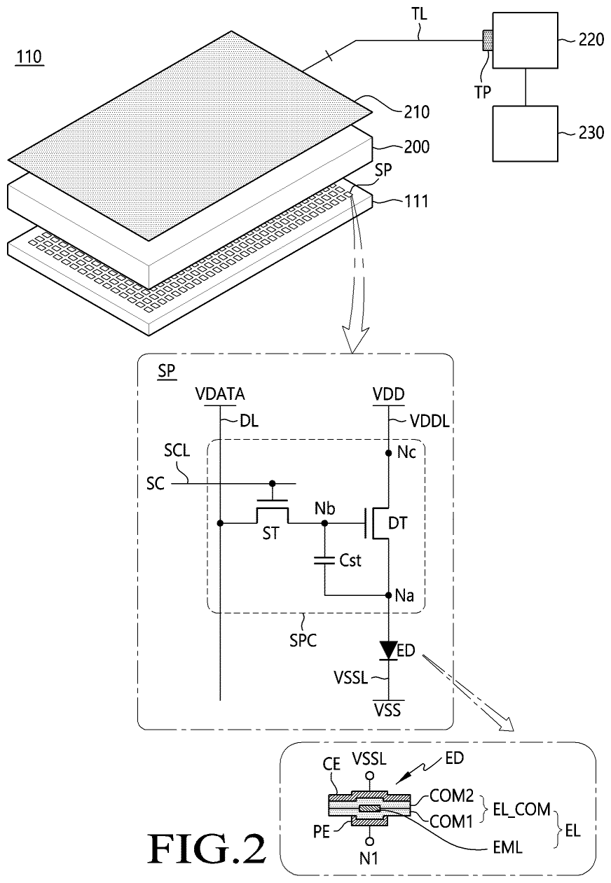

FIG. 2 illustrates an example configuration of the display device 100 according to aspects of the present disclosure.

Referring to FIG. 2, in one or more example embodiments, the display panel 110 may include a substrate 111 on which a plurality of subpixels SP are disposed, and an encapsulation layer 200 over the substrate 111. The encapsulation layer 200 may also be referred to as an encapsulation substrate or an encapsulation stack.

Referring to FIG. 2, in an example where the display device 100 is a self-emission display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but embodiments of the present disclosure are not limited thereto. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off by a scan signal SC.

The driving transistor DT can supply a driving current to the light emitting element ED. The scan transistor ST may be configured to control an electrical state of a corresponding node in the subpixel circuit SPC or to control the state or operation of the driving transistor DT. The at least one capacitor may include a storage capacitor Cst configured to maintain a voltage at a constant level during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, common driving signals including a driving voltage VDD and a base voltage VSS may be supplied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed for each subpixel SP, and the common electrode CE may be an electrode commonly disposed in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions may be provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed for each subpixel SP, or be commonly disposed across all or some of a plurality of subpixels SP. The common intermediate layer EL_COM may be commonly disposed across all or some of a plurality of subpixels SP, but aspects of the present disclosure are not limited thereto.

The emission layer EML may be disposed for each light emitting area or be commonly disposed across all or some of a plurality of light emitting areas. The common intermediate layer EL_COM may be commonly disposed across all or some of a plurality of light emitting areas and a non-light emitting area, but aspects of the present disclosure are not limited thereto.

For example, the first common intermediate layer COM1 may include a hole injection layer (HIL), an electron blocking layer (EBL), a hole transfer layer (HTL), and the like, but aspects of the present disclosure are not limited thereto. The second common intermediate layer COM2 may include an electron transfer layer (ETL), a hole blocking layer (HBL), an electron injection layer (EIL), and the like, but aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a base voltage line VSSL. A base voltage VSS, which is a type of common voltage, may be applied to the common electrode CE through a base voltage line VSSL. The pixel electrode PE may be electrically connected directly or indirectly (via another transistor) to a first node N1 of the corresponding driving transistor DT of each subpixel SP. Herein, the base voltage VSS may also be referred to as a first common voltage, a low power supply voltage, or a low voltage, and the base voltage line VSSL may also be referred to as a first common voltage line, a low power supply voltage line, or a low voltage line.

Each light emitting element ED may be configured by overlapping of a pixel electrode PE, an emission layer EML in an intermediate layer EL, and a common electrode CE. A corresponding light emitting area may be formed by each light emitting element ED. For example, a corresponding light emitting area of each light emitting element ED may include an area where a pixel electrode PE, an emission layer EML in an intermediate layer EL, and a common electrode CE overlap with each other.

In one or more embodiments, each or one or more of light emitting elements ED included in the display panel 110 may be an organic light emitting diode (OLED), an inorganic light emitting diode (LED), a quantum dot light emitting element, a micro LED, or a mini LED, but embodiments of the present disclosure are not limited thereto. In the example where each light emitting element ED is an organic light emitting diode (OLED), the corresponding intermediate layer EL of each light emitting element ED may be a layer including an organic material.

Referring to FIG. 2, the driving transistor DT may be a transistor configured to supply a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED. A data signal VDATA may be applied to the second node Nb. A driving voltage VDD, which is a type of common voltage, delivered through the driving voltage line VDDL may be applied to the third node Nc. The driving transistor DT may be connected to the first node Na and the third node Nc. Herein, the driving voltage VDD may also be referred to as a second common voltage, a high power supply voltage, or a high voltage, and the driving voltage line VDDL may also be referred to as a second common voltage line, a high power supply voltage line, or a high voltage line.

In the driving transistor DT, the second node Nb may be a gate node, the first node Na may be a source node or a drain node, and the third node Nc may be the drain node or the source node. Hereinafter, for merely convenience of explanation, discussions may be provided based on examples where the first, second, and third nodes (Na, Nb, and Nc) of the driving transistor DT are source, gate, and drain nodes, respectively. However, embodiments of the present disclosure are not limited thereto.

The scan transistor ST included in the subpixel circuit SPC illustrated in FIG. 2 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node Nb of the driving transistor DT and a data line DL. The drain electrode or source electrode of the scan transistor ST may be electrically connected to the data line DL. The source electrode or drain electrode of the scan transistor ST may be electrically connected to the second node Nb of the driving transistor DT. The gate electrode of the scan transistor ST may be electrically connected to the scan line SCL.

The storage capacitor Cst may be electrically connected between the first node Na and the second node Nb of the driving transistor DT. The storage capacitor Cst may include a first capacitor electrode electrically connected to the first node Na of the driving transistor DT or corresponding to the first node Na of the driving transistor DT, and a second capacitor electrode electrically connected to the second node Nb of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node Na and the second node Nb of the driving transistor DT. However, embodiments of the present disclosure are not limited thereto.

Each of the driving transistor DT and the scan transistor ST may be an n-type transistor or a p-type transistor, but aspects of the present disclosure are not limited thereto. For example, one of the driving transistor DT and the scan transistor ST may be one of an n-type transistor and a p-type transistor.

The display panel 110 may have a top emission structure or a bottom emission structure. In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase. In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2TIC structure”), and in some implementations, may further include one or more transistors, and/or further include one or more capacitors.

For example, the subpixel circuit SPC may have an 3TIC structure including 3 transistors and 1 capacitor. In another example, the subpixel circuit SPC may have an 8TIC structure including 8 transistors and 1 capacitor. In another example, the subpixel circuit SPC may have an 6T2C structure including 6 transistors and 2 capacitors. In another example, the subpixel circuit SPC may have an 7TIC structure including 7 transistors and 1 capacitor. However, aspects of the present disclosure are not limited thereto.

The types and number of gate signals supplied to a subpixel SP, and/or the types and number of gate lines connected to the subpixel SP may vary depending on a structure of a corresponding subpixel circuit SPC. Further, the types and number of common driving signals supplied to a subpixel SP may vary depending on a structure of a corresponding subpixel circuit SPC.

Referring to FIG. 2, since circuit elements (e.g., light emitting elements ED such as organic light emitting diodes (OLED) including an organic material) in each subpixel SP are vulnerable to external moisture or oxygen, an encapsulation layer 200 may be disposed in the display panel 110. The encapsulation layer 200 can prevent or reduce external moisture or oxygen from penetrating into the circuit elements (e.g., the light emitting elements ED). The encapsulation layer 200 may be disposed in various shapes or configurations to prevent or reduce light emitting elements ED from contacting moisture or oxygen. For example, the encapsulation layer 200 may include two or more layers in which one or more organic layers and one or more inorganic layers are alternately stacked, but aspects of the present disclosure are not limited thereto.

Referring to FIG. 2, in one or more embodiments, to provide a touch sensing function, the display device 100 may include a touch sensor layer 210 including a plurality of sensor electrodes, and a touch sensing circuit configured to sense a touch sensor disposed in the touch sensor layer 210 and determine whether a touch is applied or a location of the touch (e.g., touch coordinates). The touch sensor layer 210 may also be called a touch part or a touch sensing part.

For example, the touch sensing circuit may include a touch driving circuit 220 configured to drive and sense the touch sensor disposed in the touch sensor layer 210 to generate and output touch sensing data, and a touch controller 230 configured to determine the presence or absence of a touch or touch coordinates based on the touch sensing data from the touch driving circuit 220.

The touch sensor layer 210 may be a layer where the touch sensor is formed, and the touch sensor may be configured with a plurality of touch electrodes.

For example, the touch sensor layer 210 may be disposed outside of the display panel 110 and be disposed in a separate touch panel different from the display panel 110. In this example, the touch panel and the display panel 110 may be manufactured separately and combined during the assembly process.

In another example, the touch sensor layer 210 may be embedded into the display panel 110. When the touch sensor layer 210 is embedded inside of the display panel 110, the touch sensor layer 210 may be disposed on the substrate 111 together with signal lines and electrodes related to display driving during the process of manufacturing the display panel 110. For example, the touch sensor layer 210 may be disposed on the encapsulation layer 200. Hereinafter, for convenience of explanation, discussions are provided for examples in which the touch sensor layer 210 is embedded into the display panel 110.

In the example where the touch sensor layer 210 is embedded inside of the display panel 110, in addition to the plurality of touch electrodes serving as the touch sensor, the display panel 110 may further include a plurality of touch pads TP to which the touch driving circuit 220 is electrically connected, and a plurality of touch routing lines for electrically interconnecting the plurality of touch electrodes and the plurality of touch pads TP. The plurality of touch routing lines TL may also be referred to as a plurality of touch lines. The plurality of touch routing lines TL may correspond to a plurality of touch channels.

The touch driving circuit 220 can supply a touch driving signal to at least one of the plurality of touch electrodes, sense at least one of the plurality of touch electrodes, and generate touch sensing data based on the result of the sensing.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing, each of a plurality of touch electrodes may serve as both a driving touch electrode and a sensing touch electrode. The touch driving circuit may drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes (e.g., two adjacent touch electrodes). According to the mutual-capacitance sensing, a plurality of touch electrodes may be divided into driving touch electrodes and sensing touch electrodes. The touch driving circuit can drive the driving touch electrodes and sense the sensing touch electrodes. Touch routing lines connected to the driving touch electrodes may be referred to as driving touch routing lines, and touch routing lines connected to the sensing touch electrodes may be referred to as sensing touch routing lines.

In one or more aspects, the touch driving circuit 220 and the touch controller 230 may be implemented in separate devices or in one device. In one or more aspects, the touch driving circuit 220 and the data driving circuit 120 may be implemented in separate devices or in one device.

The display device 100 may further include a power supply circuit for supplying several types of power to the display driving circuit and/or the touch sensing circuit. The power supply circuit can supply several types of voltages and power supply voltages related to display driving to the display driving circuit or display panel 110.

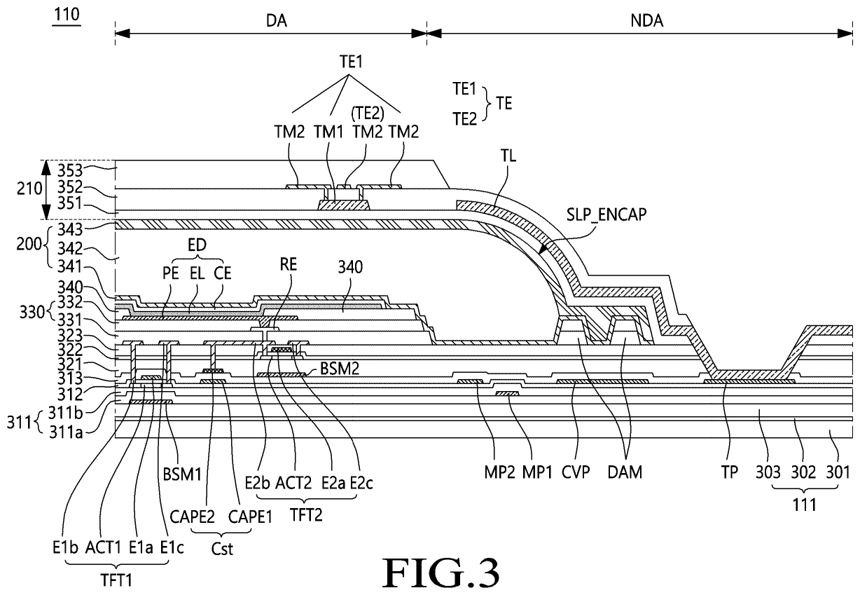

FIG. 3 is an example cross-sectional view of the display panel 110 according to embodiments of the present disclosure.

Referring to FIG. 3, in one or more example embodiments, the display panel 110 may include a substrate 111, a transistor part, a light emitting element part, and an encapsulation part, but embodiments of the present disclosure are not limited thereto.

A substrate 111 may be in the form of a single layer or multilayer. In an example where the substrate 111 is in the formed of a multilayer, the substrate 111 may include a first substrate 301, an intermediate substrate layer 302, and a second substrate 303. The intermediate substrate layer 302 may be located between the first substrate 301 and the second substrate 303. For example, each of the first substrate 301 and the second substrate 303 may be a polyimide (PI) layer, but aspects of the present disclosure are not limited thereto. The intermediate substrate layer 302 may be an inorganic insulating layer, but embodiments of the present disclosure are not limited thereto. When charges are stored in the first substrate 301, which is the polyimide layer, the intermediate substrate layer 302 can block the charges from affecting one or more transistors disposed on the second substrate 303 through the second substrate 303, which is the polyimide layer.

In addition, the intermediate substrate layer 302 can block moisture from penetrating upwardly through the first substrate 301. For example, the intermediate substrate layer 302 may be in the form of a single layer of silicon nitride (SiNx) or silicon oxide (SiOx) or a multilayer thereof or may be in the form of a double layer of silicon dioxide (SiO₂) and silicon nitride (SiNx). However, aspects of the present disclosure are not limited thereto.

The transistor part may include insulating layers (311, 312, 313, 321, 322, and 323), thin film transistors (TFT1 and TFT2), a storage capacitor Cst, and several electrodes or signal lines, which are disposed on the substrate 111.

The thin film transistors (TFT1 and TFT2) included in the transistor part may include a first thin film transistor TFT1 and a second thin film transistor TFT2.

The first thin film transistor TFT1 may include a first active layer ACT1, a first electrode Ela, a second electrode E1b, and a third electrode E1c.

The first electrode Ela may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (Ela, E1b, and E1c) are a first gate electrode Ela, a first source electrode E1b, and a first drain electrode E1c, respectively. However, aspects of the present disclosure are not limited thereto.

The first active layer ACT1 may include a first semiconductor material. For example, the first semiconductor material may include an oxide semiconductor, amorphous silicon, polysilicon, low-temperature polysilicon (LTPS), or the like, but aspects of the present disclosure are not limited thereto. The first thin film transistor TFT1 may be a p-channel transistor or an n-channel transistor, but embodiments of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively. However, aspects of the present disclosure are not limited thereto.

The second active layer ACT2 may include a second semiconductor material. For example, the second semiconductor material may include an oxide semiconductor, amorphous silicon, polysilicon, low-temperature polysilicon (LTPS), or the like, but aspects of the present disclosure are not limited thereto. The second thin film transistor TFT2 may be a p-channel transistor or an n-channel transistor, but embodiments of the present disclosure are not limited thereto.

Semiconductor materials of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. In another example, the first active layer ACT1 of the first thin film transistor TFT1 and the second active layer ACT2 of the second thin film transistor TFT2 may include a low-temperature polysilicon semiconductor material. In another example, the first active layer ACT1 of the first thin film transistor TFT1 may include a low-temperature polysilicon semiconductor material, and the second active layer ACT2 of the second thin film transistor TFT2 may include an oxide semiconductor material. In another example, the first active layer ACT1 of the first thin film transistor TFT1 may include an oxide semiconductor material, and the second active layer ACT2 of the second thin film transistor TFT2 may include a low-temperature polysilicon semiconductor material.

Transistors included in the display area DA may be used as follows.

For example, all transistors included in each subpixel SP may be implemented as the first thin film transistor TFT1. In another example, all transistors included in each subpixel SP may be implemented as the second thin film transistor TFT2. In another example, one or more of all transistors included in each subpixel SP may be implemented as the first thin film transistor TFT1, and one or more of the remaining one or more transistors may be implemented as the second thin film transistor TFT2. For example, each subpixel SP may include at least one first thin film transistor TFT1 and at least one second thin film transistor TFT2.

In the example where one or more of all transistors included in each subpixel SP are implemented as a first thin film transistor TFT1 and one or more of the remaining one or more transistors are implemented as a second thin film transistor TFT2, the following specific examples may be implemented in the display panel 110.

For example, in each subpixel SP, a driving transistor DT may be implemented as the first thin film transistor TFT1, and one or more transistors (e.g., a scan transistor ST, an emission control transistor, and the like) different from the driving transistor DT may be implemented as the second thin film transistor TFT2.

For example, in each subpixel SP, a driving transistor DT may be implemented as the second thin film transistor TFT2, and one or more transistors (e.g., a scan transistor ST, an emission control transistor, and the like) different from the driving transistor DT may be implemented as the first thin film transistor TFT1.

In FIG. 3, the second thin film transistor TFT2 connected to a pixel electrode PE of a light emitting element ED may be a driving transistor DT or a transistor different from the driving transistor DT depending on the configuration of a corresponding subpixel circuit SPC. For example, in FIG. 3, the second thin film transistor TFT2 connected to the pixel electrode PE of the light emitting element ED may be an emission control transistor connected between a driving transistor DT and the light emitting element ED.

Transistors disposed in the non-display area NDA may be uses as follows.

For example, active layers of transistors included in the gate driving circuit 130 of the gate-in-panel (GIP) type may include an oxide semiconductor material. In another example, the active layers of the transistors included in the gate driving circuit 130 of the gate-in-panel (GIP) type may include a low-temperature polysilicon semiconductor material. In another example, among active layers of transistors included in the gate driving circuit 130 of the gate-in-panel (GIP) type, one or more active layers may include a low-temperature polysilicon semiconductor material, and the remaining one or more active layers may include an oxide semiconductor material.

Referring to FIG. 3, the second active layer ACT2 of the second thin film transistor TFT2 may be located higher from the substrate 111 than the first active layer ACT1 of the first thin film transistor TFT1.

A first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be located on the first buffer layer 311, and the second active layer ACT2 of the second thin film transistor TFT2 may be located on the second buffer layer 321. The second buffer layer 321 may be located higher from the substrate 111 than the first buffer layer 311.

The storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on at least one planarization layer 330. Each of the light emitting elements ED may include a pixel electrode PE, an intermediate layer EL, and a common electrode CE.

The encapsulation part may include an encapsulation layer 200 on the plurality of light emitting elements ED. The encapsulation layer 200 may be in the form of a single layer or multilayer, but aspects of the present disclosure are not limited thereto. In addition to the encapsulation layer 200, the encapsulation part may further include at least one dam DAM to prevent or reduce a material included in the encapsulation layer 200 from overflowing. For example, when a second encapsulation layer 342 included in the encapsulation layer 200 is an organic encapsulation layer including an organic material, the dam DAM can prevent or reduce the organic material from overflowing.

Hereinafter, the stack-up configuration of the display panel 110 is described in more detail with reference to FIG. 3.

Referring to FIG. 3, the first buffer layer 311 may be disposed on the substrate 111. The first buffer layer 311 may be in the form of a single layer or multilayer. In an example where the first buffer layer 311 is in the form of a multilayer, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel region where a channel is formed, a source connection region on a first side of the channel region, and a drain connection region on a second opposing side of the channel region.

A first gate insulating layer 312 may be disposed on the first active layer ACT1 of the first thin film transistor TFT1. The first gate electrode Ela of the first thin film transistor TFT1 may be disposed on the first gate insulating layer 312. A first interlayer insulating layer 313 may be disposed on the first gate electrode Ela of the first thin film transistor TFT1. A metal layer in which the first gate electrode Ela of the first thin film transistor TFT1 is disposed may be referred to as a first gate metal layer.

The second buffer layer 321 may be disposed on the first interlayer insulating layer 313.

The second active layer ACT2 of the second thin film transistor TFT2 may be disposed on the second buffer layer 321. The second active layer ACT2 may include a channel region where a channel is formed, a source connection region on a first side of the channel region, and a drain connection region on a second opposing side of the channel region.

A second gate insulating layer 322 may be disposed on the second active layer ACT2 of the second thin film transistor TFT2. The second gate electrode E2a of the second thin film transistor TFT2 may be disposed on the second gate insulating layer 322. A second interlayer insulating layer 323 may be disposed on the second gate electrode E2a of the second thin film transistor TFT2. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 323.

The first source electrode E1b and the first drain electrode E1c of the first thin film transistor TFT1 may be connected to the source connection region and the drain connection region of the first active layer ACT1 respectively through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 may be connected to the source connection region and drain connection region of the second active layer ACT2 respectively through holes in the second interlayer insulating layer 323 and the second gate insulating layer 322.

The first source electrode E1b and the first drain electrode E1c of the first thin film transistor TFT1, and the second source electrode E2b and the second drain electrode E2c of the second thin film transistor TFT2 may include a first source-drain metal and be disposed in a first source-drain metal layer.

Referring to FIG. 3, in one or more embodiments, the storage capacitor Cst may be configured with the first capacitor electrode CAPE1 and the second capacitor electrode CAPE2. In one or more embodiments, the storage capacitor Cst may include three or more capacitor electrodes, or may include two or more capacitors connected in parallel.

Each of the first capacitor electrode CAPE1 and the second capacitor electrode CAPE2 may be disposed in several metal layers in the display panel 110.

In one or more embodiments, the first capacitor electrode CAPE1 may include the same first gate metal as the first gate electrode Ela of the first thin film transistor TFT1 on the first gate insulating layer 312, and be disposed in the first gate metal layer, but embodiments of the present disclosure are not limited thereto. In one or more aspects, the second capacitor electrode CAPE2 may be disposed on the first interlayer insulating layer 313.

The second source electrode E2b of the second thin film transistor TFT2 may be electrically connected to the second capacitor electrode CAPE2 through holes in the second interlayer insulating layer 323, the second gate insulating layer 322, and the second buffer layer 321.

For example, when the stack-up configuration of FIG. 3 is applied to the subpixel circuit of FIG. 2, the first thin film transistor TFT1 may be the scan transistor ST of FIG. 2, and the second thin film transistor TFT2 may be the driving transistor DT of FIG. 2.

The transistor part may further include several metal patterns (e.g., a first metal pattern MP1, a second metal pattern MP2, and the like). For example, the first metal pattern MP1 may be disposed between the lower buffer layer 311a and the upper buffer layer 311b included in the first buffer layer 311, but embodiments of the present disclosure are not limited thereto. The second metal pattern MP2 may include the same first gate metal as the first gate electrode Ela of the first thin film transistor TFT1 and be disposed in the first gate metal layer, but embodiments of the present disclosure are not limited thereto.

Each of the first metal pattern MP1 and the second metal pattern MP2 may be disposed in the display area DA or the non-display area NDA.

Referring to FIG. 3, the transistor part may further include a first shield pattern BSM1 disposed on the substrate 111. The first shield pattern BSM1 may overlap with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311 or may be disposed between the lower buffer layer 311a and the upper buffer layer 311b.

The transistor part may further include a second shield pattern BSM2 disposed on the substrate 111. The second shield pattern BSM2 may overlap with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor (CAPE2), but embodiments of the present disclosure are not limited thereto. In another example, the second shield pattern BSM2 may be disposed in the same first gate metal layer as the first gate electrode Ela of the first thin film transistor TFT1.

Referring to FIG. 3, the transistor part may further include a common driving signal layer CVP to which a common driving voltage is applied. The common driving signal layer CVP may be disposed in the display area DA or the non-display area NDA.

For example, a common driving voltage applied to the common driving voltage pattern CVP may be referred to as a power signal, and for example, include at least one of a driving voltage VDD and a base voltage VSS. The driving voltage VDD may be referred to as a high driving voltage (or a high power supply voltage or a high voltage), and the base voltage VSS may be referred to as a low driving voltage (or a low power supply voltage or a low voltage).

The planarization layer 330 may be disposed on the first thin film transistor TFT1 and the second thin film transistor TFT2, and be disposed under a light emitting element ED. The planarization layer 330 may be an organic insulating layer including an organic insulating material.

For example, the planarization layer 330 may be in the form of a single layer. In another example, the planarization layer 330 may include two layers. The planarization layer 330 may include a first planarization layer 331 and a second planarization layer 332. In one or more embodiments, the planarization layer 330 may include three or more layers. However, embodiments of the present disclosure are not limited thereto.

Referring to FIG. 3, the first planarization layer 331 may be disposed on the first source electrode E1b and the first drain electrode E1c of the first thin film transistor TFT1 and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed such that it covers both the first thin film transistor TFT1 and the second thin film transistor TFT2.

Referring to FIG. 3, a connection electrode RE may be disposed on the first planarization layer 331. The connection electrode RE may electrically interconnect the second source electrode E2b of the second thin film transistor TFT2 and a pixel electrode PE.

The connection electrode RE may be electrically connected to the second source electrode E2b of the second thin film transistor TFT2 through a hole of the first planarization layer 331. The second source electrode E2b of the second thin film transistor TFT2 may be electrically connected to the second capacitor electrode CAPE2 of the storage capacitor Cst.

The connection electrode RE may be disposed in a second source-drain metal layer on the first planarization layer 331 and may include a second source-drain metal.

The second planarization layer 332 may be disposed on the connection electrode RE.

Referring to FIG. 3, the light emitting element part may be disposed on the second planarization layer 332. The light emitting element ED may be disposed on the second planarization layer 332. The light emitting element ED may include the pixel electrode PE, an intermediate layer EL, and a common electrode CE. A light emitting area of the light emitting element ED may be formed in an area where the pixel electrode PE, the intermediate layer EL, and the common electrode CE overlap with, and contact, each other.

The pixel electrode PE may be disposed on the second planarization layer 332. The pixel electrode PE may be electrically connected to the connection electrode RE through a hole of the second planarization layer 332.

A bank 340 may be disposed on the pixel electrode PE. An opening of the bank 340 may expose a portion of the pixel electrode PE to form the light emitting area. The opening of the bank 340 may overlap with the portion of the pixel electrode PE.

For example, the bank 340 may include a material including a black pigment, or an organic material including a benzocyclobutene resin, a polyimide resin, an acrylic resin, a photosensitive polymer, or the like, but aspects of the present disclosure are not limited thereto. In an example where the bank 340 includes a material including a black pigment or a black dye, the bank 540 may be a black bank. In the example where the bank 340 includes a material including a black pigment or a black dye, the luminance of the display device 100 can be further improved because light from the outside or light reflected from the outside can be blocked.

The intermediate layer EL of the light emitting element ED may be disposed on a portion of the pixel electrode PE and the bank 340. The common electrode CE may be disposed on the intermediate layer EL.

Referring to FIG. 3, the encapsulation part may be disposed on the light emitting element part and be located on the common electrode CE. The encapsulation part may include an encapsulation layer 200 disposed on the common electrode CE.

The encapsulation layer 200 can prevent or reduce moisture or oxygen from penetrating into the light emitting element ED. For example, the encapsulation layer 200 can prevent or reduce moisture or oxygen from penetrating into an organic material included in the intermediate layer EL of the light emitting element ED. In one or more aspects, the encapsulation layer 200 may be in the form of a single layer or multilayer, but aspects of the present disclosure are not limited thereto.

For example, the encapsulation layer 200 may include a first encapsulation layer 341, a second encapsulation layer 342, and a third encapsulation layer 343, but aspects of the present disclosure are not limited thereto. For example, the first encapsulation layer 341 and the third encapsulation layer 343 may be inorganic encapsulation layers, and the second encapsulation layer 342 may include an organic encapsulation layer. However, aspects of the present disclosure are not limited thereto.

In one or more embodiments, a touch sensor may be embedded in the display panel 110. In this implementation, the display panel 110 may include a touch sensor layer 210 disposed on the encapsulation layer 200. For example, the touch sensor layer 210 may be a layer in which the touch sensor is disposed.

Referring to FIG. 3, the touch sensor layer 210 may include a plurality of touch electrodes TE serving as the touch sensor and include at least one touch metal layer for forming the plurality of touch electrodes TE.

For example, to form the plurality of touch electrodes TE, the touch sensor layer 210 may include a first touch metal layer in which a plurality of first touch metals TM1 are disposed, and a second touch metal layer in which a plurality of second touch metals TM2 are disposed. In this implementation, the touch sensor layer 210 may further include a touch interlayer insulating layer 352 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this implementation, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are the sensor metals. For example, two or more second touch metals TM2 and at least one first touch metal TM1 may form one first touch electrode TE1. In this implementation, the two or more second touch metals TE2 may be electrically connected by at least one first touch metal TM1.

In another example, the first touch metal layer may be a sensor metal layer, and the second touch metal layer may be a bridge metal layer. In this implementation, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are the sensor metals.

In another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this implementation, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 3, the touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulating layer 352 may be disposed on the first touch metal layer.

Referring to FIG. 3, the touch sensor layer 210 may further include a touch protection layer 353 disposed such that the touch protection layer 553 covers the touch metal layers. For example, the touch protection layer 353 may be disposed on the second touch metal layer.

For example, the touch buffer layer 351 may be an inorganic layer including an inorganic insulating material or an organic layer including an organic insulating material. The touch interlayer insulating layer 352 may be an inorganic layer including an inorganic insulating material or an organic layer including an organic insulating material. The touch protection layer 353 may be an inorganic layer including an inorganic insulating material or an organic layer including an organic insulating material.

For example, at least one of the touch buffer layer 351 and the touch interlayer insulating layer 352 may be disposed to extend from the display area DA to the non-display area NDA. The touch protection layer 353 may be disposed to extend from the display area DA to the non-display area NDA.

A touch routing line TL may electrically connect a touch electrode TE and a touch pad TP. The touch routing line TL may be formed by at least one of the first touch metal TM1 and the second touch metal TM2.

For example, the touch routing line TL may be formed by the first touch metal TM1. For example, the touch routing line TL may be formed by the second touch metal TM2. For example, the touch routing line TL may be formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL may be electrically connected through a hole in the insulating layer 352.

For example, one touch routing line TL may include a plurality of line portions, and each of the plurality of line portions may be a single line portion or a double line portion. For example, the single line portion may be a line portion with one signal path, and the double line portion may be a line portion with two signal paths connected in parallel.

The touch routing line TL may extend along an inclined surface of the encapsulation layer 200, extend over an upper portion of at least one dam DAM and reach a touch pad TP.

The touch buffer layer 351 may have an opening to expose at least a portion of the touch pad TP. The touch routing line TL may be electrically connected to the touch pad TP through the opening of the touch buffer layer 351. The touch interlayer insulating layer 352 may be disposed on a portion of the touch routing line TL and may extend to an area where the touch pad TP is disposed. The touch protection layer 353 may be disposed only in the display area DA or may extend to the non-display area NDA and be disposed on the touch routing line TL. In one or more aspects, the touch protection layer 353 may extend further to an upper portion of the touch pad TP. Each of a plurality of touch electrodes TE may be a mesh-type electrode configured to have a mesh with a plurality of openings. In this implementation, each of the plurality of touch electrodes TE may include at least one second touch metal TM2. However, embodiments of the present disclosure are not limited thereto.

For example, the plurality of touch electrodes TE may include at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which serves as the touch sensor, may be electrically connected through at least one first touch metal TM1, which is the bridge metal. For example, two second touch metals TM2 spaced apart from each other may be electrically connected by a first touch metal TM1 to form one first touch electrode TE1.

Referring to FIG. 3, the plurality of first touch metals TM1 and the plurality of second touch metals TM2 may be disposed not to overlap with the light emitting element ED. The plurality of first touch metals TM1 and the plurality of second touch metals TM2 may overlap with the bank 340. According to these configurations, the display panel 110 can provide an advantage of improving the emission efficiency of the light emitting element ED.

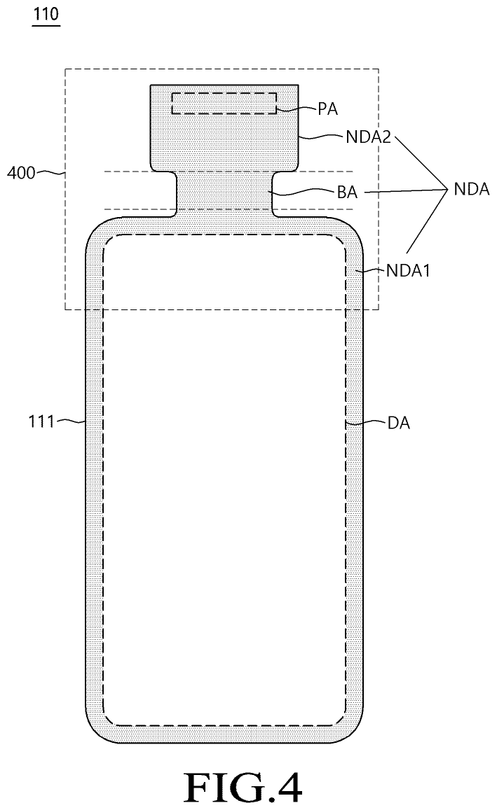

FIG. 4 is an example plan view of the display panel 110 according to embodiments of the present disclosure.

Referring to FIG. 4, in one or more example embodiments, the substrate 111 of the display panel 110 may include the display area DA and the non-display area NDA. The display area DA and the non-display area NDA may be areas defined in the display panel 110.

The display area DA may be an area where an image is displayed and be an area where a plurality of subpixels SP are disposed.

The non-display area NDA may be an area where an image is not displayed, and be an area except for the display area DA. A subpixel SP may not be disposed in the non-display area ND). In one or more embodiments, at least one dummy subpixel, which is not directly involved in image displaying, may be disposed in the non-display area NDA.

In one or more embodiments, the non-display area NDA may include a first non-display area NDA1, a bending area BA, and a second non-display area NDA2.

The first non-display area NDA1 may be located adjacent to the display area DA and may be an area located closest to the display area DA among the first non-display area NDA1, the bending area BA, and the second non-display area NDA2.

The second non-display area NDA2 may include a pad area allowing several pads to be disposed and be an area located farthest away from the display area DA among the first non-display area NDA1, the bending area BA, and the second non-display area NDA2.

The bending area BA may be an area allowing the substrate 111 to be bent and may be located between the first non-display area NDA1 and the second non-display area NDA2.

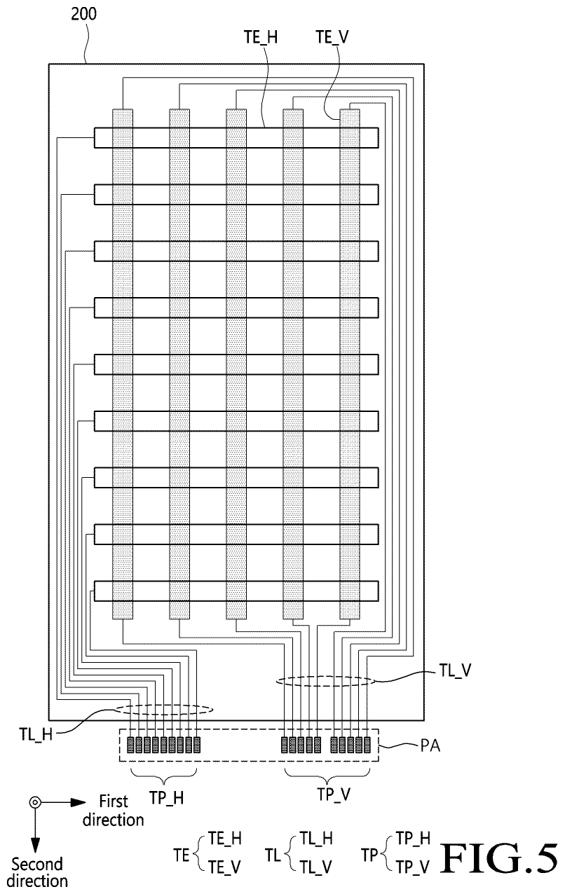

FIG. 5 illustrates an example touch sensor structure included in the display device 100 according to embodiments of the present disclosure.

Referring to FIG. 5, in one or more example embodiments, a touch sensor included in the display device 100 may include a plurality of touch electrodes TE. The plurality of touch electrodes TE may include a plurality of horizontal touch electrodes TE_H and a plurality of vertical touch electrodes TE_V.

The plurality of touch electrodes TE may be located in the display area DA and may be disposed on the encapsulation layer 200.

Each of the plurality of horizontal touch electrodes TE_H may be disposed in a first direction, and each of the plurality of vertical touch electrodes TE_V may be disposed in a second direction different from the first direction.

Herein, the first direction and the second direction may be relatively different directions, and for example, the first direction may be an x-axis direction and the second direction may be a y-axis direction. In another example, the first direction may be the y-axis direction and the second direction may be the x-axis direction. The first direction and the second direction may be orthogonal to each other, or may not be orthogonal. Herein, rows and columns are relatively defined and are interchanged depending on a direction at which the display device 100 or the display panel 110 is viewed. For example, the first direction may be a direction in which gate lines GL extend, and the second direction may be a direction in which data lines DL extend. In another example, the first direction may be a direction in which data lines DL extend, and the second direction may be a direction in which gate lines GL extend.

In one or more aspects, each of the plurality of horizontal touch electrodes TE_H may be a touch electrode having a bar shape, and each of the plurality of vertical touch electrodes TE_V may be a touch electrode having a bar shape. In this implementation, for example, the plurality of horizontal touch electrodes TE_H may be disposed in the first touch metal layer, and the plurality of vertical touch electrodes TE_V may be disposed in the second touch metal layer. In another example, the plurality of horizontal touch electrodes TE_H may be disposed in the second touch metal layer, and the plurality of vertical touch electrodes TE_V may be disposed in the first touch metal layer.

In another example, the plurality of horizontal touch electrodes TE_H may include a plurality of horizontal touch electrodes and a plurality of horizontal bridge electrodes for electrically interconnecting the plurality of horizontal touch electrodes. The plurality of vertical touch electrodes TE_V may include a plurality of vertical touch electrodes and a plurality of vertical bridge electrodes for electrically interconnecting the plurality of vertical touch electrodes. In this implementation, for example, the plurality of horizontal touch electrodes and the plurality of vertical touch electrodes may be disposed in the second touch metal layer, and the plurality of horizontal bridge electrodes and the plurality of vertical bridge electrodes may be disposed in the first touch metal layer.

The roles (functions) of the plurality of horizontal touch electrodes TE_H and the plurality of vertical touch electrodes TE_V may be distinct. For example, the plurality of horizontal touch electrodes TE_H may be driving electrodes (or transmitting electrodes) to which a touch driving signal is applied by the touch driving circuit 220, and the plurality of vertical touch electrodes TE_V may be sensing electrodes (or receiving electrodes) sensed by the touch driving circuit 220. In this example, the plurality of horizontal touch electrodes TE_H may be referred to as driving touch electrodes (or transmitting touch electrodes), and the plurality of vertical touch electrodes TE_V may be referred to as sensing touch electrodes (or receiving touch electrodes).

In another example, the plurality of vertical touch electrodes TE_V may be driving electrodes (or transmitting electrodes) to which a touch driving signal is applied by the touch driving circuit 220, and the plurality of horizontal touch electrodes TE_H may be sensing electrodes (or receiving electrodes) sensed by the touch driving circuit 220. In this example, the plurality of vertical touch electrodes TE_V may be referred to as driving touch electrodes (or transmitting touch electrodes), and the plurality of horizontal touch electrodes TE_H may be referred to as sensing touch electrodes (or receiving touch electrodes).

Referring to FIG. 5, the touch sensor structure may further include a plurality of touch routing lines TL. The plurality of touch routing lines TL may include a plurality of horizontal touch routing lines TL_H and a plurality of vertical touch routing lines TL_V.

The plurality of touch routing lines TL may be disposed in the non-display area NDA. A portion (e.g., a portion connected to a touch electrode) of at least one of the plurality of touch routing lines TL may be located in the display area DA.

The touch sensor structure may further include a plurality of touch pads TP. The plurality of touch pads TP may include a plurality of horizontal touch pads TP_H and a plurality of vertical touch pads TP_V. The plurality of touch pads TP may be disposed in the non-display area NDA.

The plurality of horizontal touch routing lines TL_H may electrically interconnect the plurality of horizontal touch electrodes TE_H and the plurality of horizontal touch pads TP_H. The plurality of vertical touch routing lines TL_V may electrically interconnect the plurality of vertical touch electrodes TE_V and the plurality of vertical touch pads TP_V.

A corresponding one or corresponding two or more of the plurality of horizontal touch routing lines TL_H may be connected to each of the plurality of horizontal touch electrodes TE_H. A corresponding one or corresponding two or more of the plurality of vertical touch routing lines TL_V may be connected to each of the plurality of vertical touch electrodes TE_V.

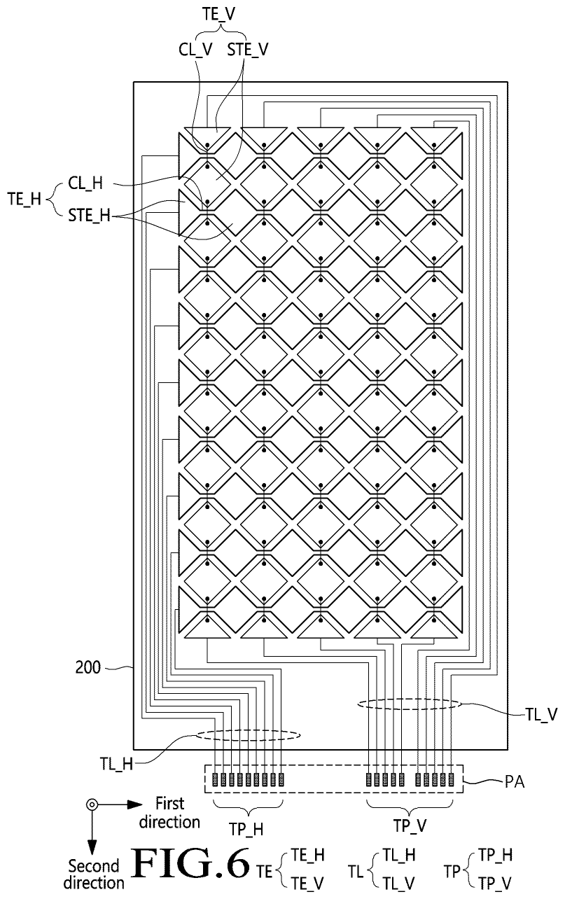

FIG. 6 illustrates another example touch sensor structure included in the display device 100 according to aspects of the present disclosure.

Referring to FIG. 6, in one or more example embodiments, a touch sensor included in the display device 100 may include a plurality of touch electrodes TE. The plurality of touch electrodes TE may include a plurality of horizontal touch electrodes TE_H and a plurality of vertical touch electrodes TE_V.

The plurality of touch electrodes TE may be located in the display area DA and be disposed on the encapsulation layer 200.

Each of the plurality of horizontal touch electrodes TE_H may include two or more horizontal sub-touch electrodes STE_H disposed in the same row (or column) and one or more horizontal bridge electrodes CL_H electrically interconnecting the two or more horizontal sub-touch electrodes STE_H. For example, as in the example of FIG. 6, two or more horizontal sub-touch electrodes STE_H and one or more horizontal bridge electrodes CL_H included in one horizontal touch electrode TE_H may be an integrally formed touch metal (e.g., a second touch metal). In another example, as in the example of FIG. 6, two or more horizontal sub-touch electrodes STE_H may be disposed in a second touch metal layer, and one or more horizontal bridge electrodes CL_H may be disposed in a first touch metal layer.

Each of the plurality of vertical touch electrodes TE_V may include two or more vertical sub-touch electrodes STE_V disposed in the same column (or row) and one or more vertical bridge electrodes CL_V electrically interconnecting the two or more vertical sub-touch electrodes STE_V. For example, two or more vertical sub-touch electrodes STE_V and one or more vertical bridge electrodes CL_V included in one vertical touch electrode TE_V may be an integrally formed touch metal (e.g., a second touch metal). In another example, as in the example of FIG. 6, two or more vertical sub-touch electrodes STE_V may be disposed in a second touch metal layer, and one or more vertical bridge electrodes CL_V may be disposed in a first touch metal layer.

In an area where a horizontal touch electrode TE_H and a vertical touch electrode TE_V intersect each other (which may be referred to as a touch electrode intersection area), a horizontal bridge electrode CL_H and a vertical bridge electrode CL_V may intersect each other.

In the touch electrode intersection area, when the horizontal bridge electrode CL_H and the vertical bridge electrode CL_V intersect, the horizontal bridge electrode CL_H and the vertical bridge electrode CL_V may be needed to be located in different layers.

Accordingly, in order for the plurality of horizontal touch electrodes TE_H and the plurality of vertical touch electrodes TE_V to be disposed to intersect each other, the plurality of horizontal sub-touch electrodes STE_H, the plurality of horizontal bridge electrodes CL_H, the plurality of vertical sub-touch electrodes STE_V, and the plurality of vertical bridge electrodes CL_V may be located in two or more layers.

Referring to FIG. 6, in one or more embodiments, the touch sensor structure may further include a plurality of touch routing lines TL. The plurality of touch routing lines TL may include a plurality of horizontal touch routing lines TL_H and a plurality of vertical touch routing lines TL_V.

The plurality of touch routing lines TL may be disposed in the non-display area NDA. A portion (e.g., a portion connected to a touch electrode) of at least one of the plurality of touch routing lines TL may be located in the display area DA.

In one or more embodiments, the touch sensor structure may further include a plurality of touch pads TP. The plurality of touch pads TP may include a plurality of horizontal touch pads TP_H and a plurality of vertical touch pads TP_V. The plurality of touch pads TP may be disposed in the non-display area NDA.

Referring to FIG. 6, each of the plurality of horizontal touch electrodes TE_H may be electrically connected to a corresponding horizontal touch pad TP_H via one or more horizontal touch routing lines TL_H. At least one of two horizontal sub-touch electrodes STE_H disposed at the outermost sides among two or more horizontal sub-touch electrodes STE_H included in one horizontal touch electrode TE_H may be electrically connected to a corresponding horizontal touch pad TP_H via a horizontal touch routing line TL_H.

Each of the plurality of vertical touch electrodes TE_V may be electrically connected to a corresponding vertical touch pad TP_V via one or more vertical touch routing lines TL_V. For example, at least one of two vertical sub-touch electrodes STE_V disposed on the outermost sides among two or more vertical sub-touch electrodes STE_V included in one vertical touch electrode TE_V may be electrically connected to a corresponding vertical touch pad TP_V through a vertical touch routing line TL_V.

In one or more embodiments, as illustrated in FIG. 6, the plurality of horizontal touch electrodes TE_H and the plurality of vertical touch electrodes TE_V may be disposed on an encapsulation layer 200. The plurality of horizontal sub-touch electrodes STE_H and the plurality of horizontal bridge electrodes CL_H included in the plurality of horizontal touch electrodes TE_H may be disposed on the encapsulation layer 200. The plurality of vertical sub-touch electrodes STE_V and the plurality of vertical bridge electrodes CL_V included in the plurality of vertical touch electrodes TE_V may be disposed on the encapsulation layer 200.

Each of the plurality of horizontal touch routing lines TL_H may be disposed on the encapsulation layer 200, extend outside of the encapsulation layer 200, and be electrically connected to a corresponding one of the plurality of horizontal touch pads TP_H in a pad area PA located in an outward area from the encapsulation layer 200.

Each of the plurality of vertical touch routing lines TL_V may be disposed on the encapsulation layer 200, extend outside of the encapsulation layer 200, and be electrically connected to a corresponding one of the plurality of vertical touch pads TP_V in a pad area PA located in an outward area from the encapsulation layer 200.

The encapsulation layer 200 may be located in the display area DA, and in one or more aspects, may be extended to the non-display area NDA.

As described above, the plurality of touch routing lines TL may be disposed in the non-display area NDA. Therefore, the size of the non-display area NDA may increase because the non-display area NDA needs to include a space where the plurality of touch routing lines TL are disposed.

To address this issue, the size of the non-display area NDA may be reduced by reducing a line width of each of the plurality of touch routing lines TL or reducing a space between the plurality of touch routing lines TL.

However, when the line width of each of the plurality of touch routing lines TL is reduced, an electrical resistance of each of the plurality of touch routing lines TL may increase. Thereby, the signal delay (RC delay) of each of the plurality of touch routing lines TL may increase, and the performance of touch driving and touch sensing may be degraded.

In addition, when the space between the plurality of touch routing lines TL is reduced, a coupling capacitance (which may be also referred to as a coupling noise) between the plurality of touch routing lines TL may increase. Thereby, the signal delay (e.g., resistor-capacitor (RC) delay) of each of the plurality of touch routing lines TL may increase, and the performance of touch driving and touch sensing may be degraded.

In addition, since respective lengths of the plurality of touch routing lines TL may be different, the electrical characteristics (e.g., resistance, capacitance, etc.) of each of the plurality of touch routing lines TL may be different from each other. Thereby, the performance of touch driving and touch sensing may be degraded.

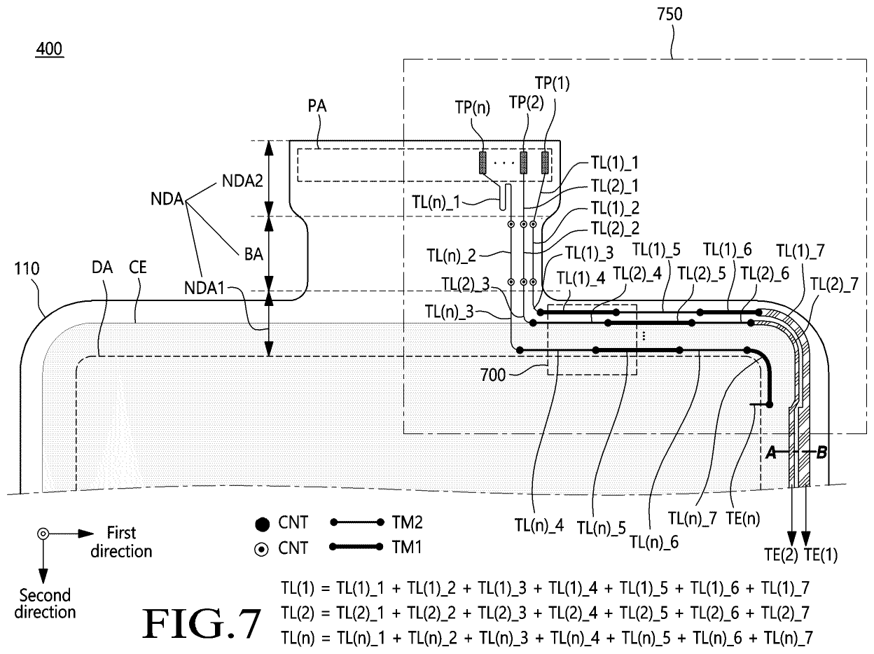

To address these issues, in one or more aspects, the display device 100 may include a structure capable of reducing the size of the non-display area NDA without a degradation of the performance of touch driving and touch sensing as discussed below. Hereinafter, such an improved touch routing line structure will be described with reference to FIGS. 7 to 14.

FIGS. 7 to 10 illustrate example touch routing line structures in the display panel 110 according to embodiments of the present disclosure.

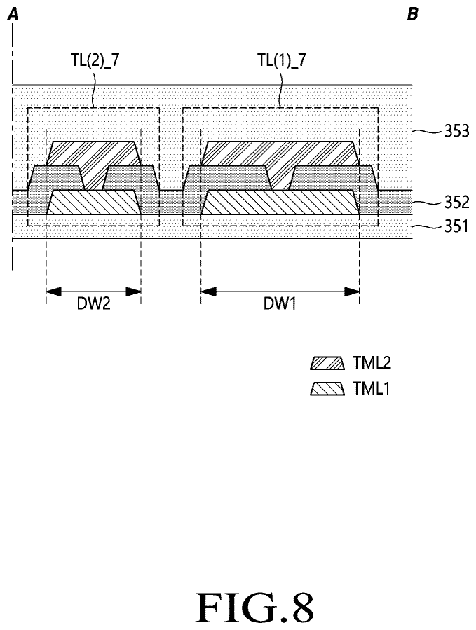

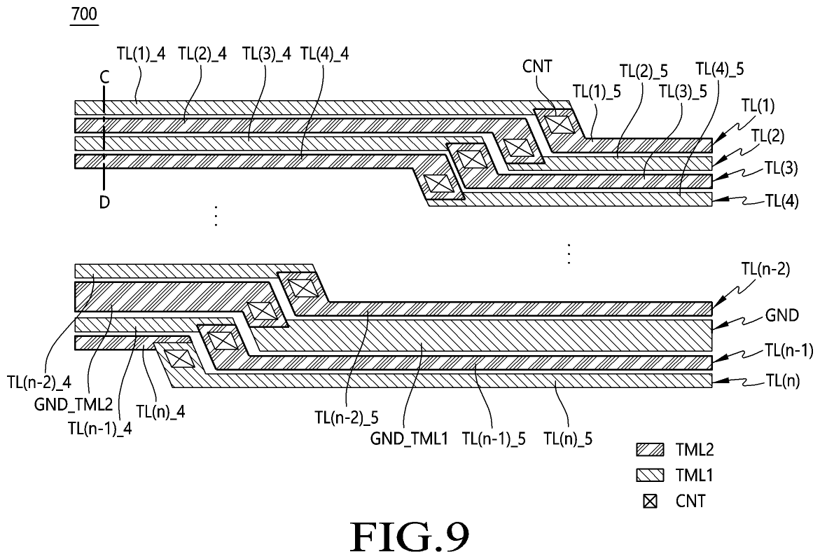

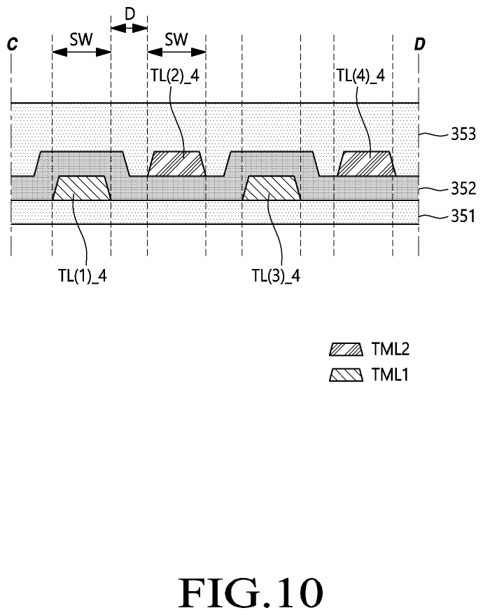

FIG. 7 is an enlarged plan view of a partial area 400 of FIG. 4 according to embodiments of the present disclosure. FIG. 8 is a cross-sectional view taken along line A-B of FIG. 7 according to embodiments of the present disclosure. FIG. 9 illustrates n touch routing lines (TL(1)˜TL(n)) disposed in a partial area 700 of FIG. 7 according to embodiments of the present disclosure. FIG. 10 is a cross-sectional view taken along line C-D of FIG. 8 according to embodiments of the present disclosure.

Referring to FIG. 7, in one or more example embodiments, the display panel 110 may include the substrate 111, a plurality of touch electrodes TE, a plurality of touch pads TP, and a plurality of touch routing lines TL. The plurality of touch routing lines TL may correspond to a plurality of touch channels.

The plurality of touch electrodes TE may include n touch electrodes (TE(1) to TE(n)). The plurality of touch pads TP may include n touch pads (TP(1) to TP(n)). The plurality of touch routing lines TL may include n touch routing lines (TL(1) to TL(n)). Here, n may be a natural number greater than or equal to 2.

The substrate 111 may include the display area DA and the non-display area NDA adjacent to the display area DA.

The n touch electrodes (TE(1) to TE(n)) may be disposed on the substrate 111 and may be located in the display area DA. The n touch electrodes (TE(1) to TE(n)) may include first to nth touch electrodes (TE(1) to TE(n)).

The n touch pads (TP(1) to TP(n)) may be disposed on the substrate 111 and may be located in the non-display area NDA. The n touch pads (TP(1) to TP(n)) may include first to nth touch pads (TP(1) to TP(n)).

The n touch routing lines (TL(1) to TL(n)) may be disposed on the substrate 111, electrically interconnect the n touch electrodes (TE(1) to TE(n)) and the n touch pads (TP(1) to TP(n)), and disposed in a portion of an outer edge of the display area DA. The n touch routing lines (TL(1) to TL(n)) may include first to nth touch routing lines (TL(1) to TL(n)).

For example, the n touch routing lines (TL(1) to TL(n)) may be touch routing lines disposed in a portion (e.g., a right outer edge) of the outer edge of the display area DA among all touch routing lines TL disposed in the display panel 110. In one or more aspects, one or more touch routing lines may be also disposed in another portion (e.g., a left outer edge) of the outer edge of the display area DA among all touch routing lines TL disposed in the display panel 110. For example, as shown in the example of FIG. 7, the n touch routing lines (TL(1) to TL(n)) may be touch routing lines disposed in the first non-display area NDA1 in the right outer edge of the display area DA. For example, one or more touch routing lines may be also disposed in the first non-display area NDA1 in the left outer edge of the display area DA.

Referring to FIG. 7, a first touch routing line TL(1) among the n touch routing lines (TL(1) to TL(n)) may electrically interconnect a first touch electrode TE(1) among the n touch electrodes (TE(1) to TE(n)) and a first touch pad TP(1) among the n touch pads (TP(1) to TP(n)).

An nth touch routing line TL(n) among the n touch routing lines (TL(1) to TL(n)) may electrically interconnect an nth touch electrode TE(n) among the n touch electrodes (TE(1) to TE(n)) and an nth touch pad TP(n) among the n touch pads (TP(1) to TP(n)).

Referring to FIG. 7, the nth touch routing line TL(n) may be disposed closer to the display area DA than the first touch routing line TL(1). For example, the first touch routing line TL(1) may be disposed further outward than the nth touch routing line TL(n).

For example, among the n touch routing lines (TL(1) to TL(n)), the first touch routing line TL(1) may be disposed at the outermost edge, and the nth touch routing line TL(n) may be disposed at the innermost edge. For example, among the n touch routing lines (TL(1) to TL(n)), the first touch routing line TL(1) may be disposed furthest away from the display area DA, and the nth touch routing line TL(n) may be disposed closest to the display area DA.

According to these configurations, in the first non-display area NDA1, the first touch routing line TL(1) may have a length greater than the nth touch routing line TL(n).

Referring to FIG. 7, the first touch routing line TL(1) may include a first single line portion (TL(1)_4, TL(1)_5, and TL(1)_6) and a first double line portion TL(1)_7. The first single line portion (TL(1)_4, TL(1)_5, and TL(1)_6) and the first double line portion TL(1)_7 may be electrically connected to each other.

Herein, the term “single line portion” may mean a line portion having one signal path, and the term “double line portion” may mean a line portion having two signal paths connected in parallel.

For example, one or more single line portions may be disposed in an area adjacent to the bending area BA among area of the first non-display area NDA1 and be disposed in a first direction (e.g., the row direction). One or more double line portions may be disposed in areas on left and right sides of the display area DA among areas of the first non-display area NDA1 and be disposed in a second direction (e.g., the column direction).

Referring to FIG. 7, in the first touch routing line L (1)_1, the first single line portion (TL(1)_4, TL(1)_5, and TL(1)_6) may be electrically connected to the first touch electrode TE(1) through the first double line portion TL(1)_7.

In the first touch routing line TL(1)_1, the first double line portion TL(1)_7 may be further away from the first touch pad TP(1) than the first single line portion (TL(1)_4, TL(1)_5, and TL(1)_6).

As described above, the first touch routing line TL(1) may have a considerably long length because it is disposed at the outermost edge of the first non-display area NDA1. However, since the first touch routing line TL(1) includes the first double line portion TL(1)_7, the resistance of the first touch routing line TL(1) can be reduced despite its long length.

Referring to FIG. 7, the first single line portion (TL(1)_4, TL(1)_5, and TL(1)_6) of the first touch routing line TL(1)_1 may be disposed to extend in the first direction in which gate lines GL extends.

The first double line portion TL(1)_7 of the first touch routing line TL(1)_1 may be disposed to extend in the second direction in which data lines DL extends. The first double line portion TL(1)_7 of the first touch routing line TL(1)_1 may further include a portion extending in the first direction in which gate lines GL extends.

The nth touch routing line TL(n) may include an nth single line portion (TL(n)_4, TL(n)_5, TL(n)_6, and TL(n)_7) electrically connected to the nth touch electrode TE(n).

While the first touch routing line TL(1) has a double line portion in the first non-display area NDA1, the nth touch routing line TL(n) does not have a double line portion in the first non-display area NDA1.

As described above, the first touch routing line TL(1) may be disposed at the outermost edge in the first non-display area NDA1, and the nth touch routing line TL(n) may be disposed at the innermost edge in the first non-display area NDA1. According to this configuration, there may occur a difference in length between the first touch routing line TL(1) and the nth touch routing line TL(n) in the first non-display area NDA1. This may cause a difference in resistance between the first touch routing line TL(1) and the nth touch routing line TL(n).

However, according to the configurations discussed above, the first touch routing line TL(1) having a long length in the first non-display area NDA1 may include the double line portion TL(1)_7, and the nth touch routing line TL(n) having a short length in the first non-display area NDA1 may not include a double line portion. Accordingly, a difference in resistance between the first touch routing line TL(1) and the nth touch routing line TL(n) can be significantly reduced.

Referring to FIG. 7, in the case of the first touch routing line TL(1), the first double line portion TL(1)_7 disposed in the first non-display area NDA1 may be electrically connected to the first touch electrode TE(1). However, in the case of the nth touch routing line TL(n), since there is no double line portion in the first non-display area NDA1, the nth single line portion (TL(n)_4, TL(n)_5, TL(n)_6, and TL(n)_7) can be electrically connected to the nth touch electrode TE(n).

Referring to FIGS. 7, 9, and 10, the first single line portion (TL(1)_4, TL(1)_5, and TL(1)_6) of the first touch routing line TL(1) may include first lower metal portions (TL(1)_4, and TL(1)_6) disposed in a first touch metal layer TML1, and a first upper metal portion TL(1)_5 disposed in a second touch metal layer TML2 different from the first touch metal layer TML1.

In the first single line portion (TL(1)_4, TL(1)_5, and TL(1)_6) of the first touch routing line TL(1), the first lower metal portions (TL(1)_4, and TL(1)_6) and the first upper metal portion TL(1)_5 may be disposed alternately. For example, the first lower metal portion TL(1)_4, the first upper metal portion TL(1)_5, and the first lower metal portion TL(1)_6 may be disposed in this sequential order.

Referring to FIGS. 9 and 10, in a single line portion area 700 of the first non-display area NDA1, the first single line portion of the first touch routing line TL(1) includes the first lower metal portion TL(1)_4 and the first upper metal portion TL(1)_5, and one end among both ends of the first lower metal portion TL(1)_4) and the other end closer to the one end of the first lower metal portion TL(1)_4 among both ends of the first upper metal portion TL(1)_5 may be electrically connected through a contact hole CNT. Here, the first lower metal portion TL(1)_4 and the first upper metal portion TL(1)_5 may be sequential paths through which a same touch-related signal is delivered. For example, after having passed through the first lower metal portion TL(1)_4, a touch-related signal may pass through the first upper metal portion TL(1)_5. In another example, after having passed through the first upper metal portion TL(1)_5, a touch-related signal may pass through the first lower metal portion TL(1)_4. Here, the touch-related signal may be a touch driving signal supplied to the first touch electrode TE(1) from the touch driving circuit 220 or a touch sensing signal in which an electrical signal on the first touch electrode TE(1) is transferred to the touch driving circuit 220.

In the single line portion area 700, a second single line portion of a second touch routing line TL(2) may include a second upper metal portion TL(2)_4 and a second lower metal portion TL(2)_5, and one end among both ends of the second upper metal portion TL(2)_4 and the other end closer to the one end of the second upper metal portion TL(2)_4 among both ends of the second lower metal portion TL(2)_5 may be electrically connected through a contact hole CNT.

In the single line portion area 700, a third single line portion of a third touch routing line TL(3) may include a third lower metal portion TL(3)_4 and a third upper metal portion TL(3)_5, and one end among both ends of the third lower metal portion TL(3)_4 and the other end closer to the one end of the third lower metal portion TL(3)_4 among both ends of the third upper metal portion TL(3)_5 may be electrically connected through a contact hole CNT.

In the single line portion area 700, a fourth single line portion of a fourth touch routing line TL(4) may include a fourth upper metal portion TL(4)_4 and a fourth lower metal portion TL(4)_5, and one end among both ends of the fourth upper metal portion TL(4)_4 and the other end closer to the one end of the fourth upper metal portion TL(4)_4 among both ends of the fourth lower metal portion TL(4)_5 may be electrically connected through a contact hole CNT.

In the single line portion area 700, an (n−2)th single line portion of an (n−2)th touch routing line TL(n−2) may include an (n−2)th lower metal portion TL(n−2)_4 and an (n−2)th upper metal portion TL(n−2)_5, and one end among both ends of the (n−2)th lower metal portion TL(n−2)_4 and the other end closer to the one end of the (n−2)th lower metal portion TL(n−2)_4 among both ends of the (n−2)th upper metal portion TL(n−2)_5 may be electrically connected through a contact hole CNT.

In the single line portion area 700, an (n−1)th single line portion of an (n−1)th touch routing line TL(n−1) may include an (n−1)th lower metal portion TL(n−1)_4 and an (n−1)th upper metal portion TL(n−1)_5, and one end among both ends of the (n−1)th lower metal portion TL(n−1)_4 and the other end closer the one end of the (n−1)th lower metal portion TL(n−1)_4 among both ends of the (n−2)th upper metal portion TL(n−2)_5 may be electrically connected through a contact hole CNT.

In the single line portion area 700, the nth single line portion of the nth touch routing line TL(n) may include an nth upper metal portion TL(n)_4 and an nth lower metal portion TL(n)_5, and one end among both ends of the nth upper metal portion TL(n)_4 and the other end closer to the one end of the nth upper metal portion TL(n)_4 among both ends of the nth lower metal portion TL(n)_5 may be electrically connected through a contact hole CNT.

Referring to FIG. 9, in one or more aspects, the display panel 110 may further include a ground line GND disposed between two touch routing lines among the n touch routing lines (TL(1) to TL(n)). For example, the ground line GND may be disposed between the (n−1)th touch routing line TL(n−1) and the (n−2)th touch routing line TL(n−2). For example, the (n−1)th touch routing line TL(n−1) disposed on one side of the ground line GND may be a driving touch routing line (or a sensing touch routing line), and the (n−2)th touch routing line TL(n−2) disposed on the other side of the ground line GND may be the sensing touch routing line (or the driving touch routing line). For example, the driving touch routing line and the sensing touch routing line may be shielded by the ground line GND.

The ground line GND may be disposed in various metal layers. For example, the ground line GND may be disposed in the same metal layer as the plurality of touch routing lines TL. For example, the ground line GND may have the same vertical structure as the plurality of touch routing lines TL.

Referring to FIG. 9, the ground line GND may include a first ground line GND_TML1 disposed in the first touch metal layer TML1 and a second ground line GND_TML2 disposed in the second touch metal layer TML2, and one end among both ends of the second ground line GND_TML2 and the other end closer to the one end of the second ground line GND_TML2 among both ends of the first ground line GND_TML1 may be electrically connected through a contact hole CNT.

Referring to FIGS. 7 and 8, the first double line portion TL(1)_7 of the first touch routing line TL(1) may include the first touch metal layer TML1 and the second touch metal layer TML2 overlapping with each other and electrically connecting each other.

Both the first touch metal layer TML1 and the second touch metal layer TML2 included in the first double line portion TL(1)_7 may be paths through which a same touch-related signal is transferred simultaneously.

For example, a touch-related signal may pass through the first touch metal layer TML1 and the second touch metal layer TML2 in parallel. Here, the touch-related signal may be a touch driving signal supplied to the first touch electrode TE(1) from the touch driving circuit 220 or a touch sensing signal in which an electrical signal on the first touch electrode TE(1) is transferred to the touch driving circuit 220.

Referring to FIG. 7, the second touch routing line TL(2) may electrically interconnect a second touch electrode TE (2) among the n touch electrodes (TE(1) to TE(n)) and a second touch pad TP (2) among the n touch pads (TP(1) to TP(n)).

Referring to FIG. 7, the second touch routing line TL(2) may be disposed adjacent to the first touch routing line TL(1) and be disposed closer to the display area DA than the first touch routing line TL(1).

Referring to FIG. 7, the second touch routing line TL(2) may include a second single line portion (TL(2)_4, TL(2)_5, and TL(2)_6) and a second double line portion TL(2)_7. In the second touch routing line TL(2)_1, the second double line portion TL(2)_7 may be further away from the second touch pad TP (2) than the second single line portion (TL(2)_4, TL(2)_5, and TL(2)_6).

Referring to FIG. 7, in the second touch routing line TL(2), the second single line portion (TL(2)_4, TL(2)_5, and TL(2)_6) and the second double line portion TL(2)_7 may be electrically connected to each other. In the second touch routing line TL(2), the second single line portion (TL(2)_4, TL(2)_5, and TL(2)_6) may be electrically connected to a second touch electrode TE (2) through the second double line portion TL(2)_7.

Referring to FIGS. 7, 9, and 10, the second single line portion (TL(2)_4, TL(2)_5, and TL(2)_6) of the second touch routing line TL(2) may include the second lower metal portion TL(2)_5 disposed in the first touch metal layer TML1 and the second upper metal portion (TL(2)_4, and TL(2)_6) disposed in the second touch metal layer TML2.

Referring to FIG. 7, in the second single line portion (TL(2)_4, TL(2)_5, and TL(2)_6) of the second touch routing line TL(2), the second lower metal portion TL(2)_5 and the second upper metal portion (TL(2)_4 and TL(2)_6) may be disposed alternately. For example, the second upper metal portion TL(2)_4, the second lower metal portion TL(2)_5, and the second upper metal portion TL(2)_6 may be disposed in this sequential order.

Referring to FIG. 8, the second double line portion TL(2)_7 of the second touch routing line TL(2) may include the first touch metal layer TML1 and the second touch metal layer TML2 overlapping with each other and electrically connecting each other at two or more points.

Referring to FIGS. 7, 9, and 10, the first lower metal portion (TL(1)_4 and TL(1)_6) of the first touch routing line TL(1) may be disposed adjacent to the second upper metal portion (TL(2)_4 and TL(2)_6) of the second touch routing line TL(2). The first upper metal portion TL(1)_5 of the first touch routing line TL(1) may be disposed adjacent to the second lower metal portion TL(2)_5 of the second touch routing line TL(2).

As described above, even when the first touch routing line TL(1) and the second touch routing line TL(2) are disposed adjacent to each other, as the first single line portion of the first touch routing line TL(1) and the second single line portion of the second touch routing line TL(2) are disposed on different metal layers, therefore, a distance D between the first touch routing line TL(1) and the second touch routing line TL(2) can be reduced. According to this configuration, a size of an area where a plurality of touch routing lines TL are disposed in the first non-display area NDA1 can be significantly reduced. Accordingly, the size of the first non-display area NDA1 can be reduced.

Further, even when the first touch routing line TL(1) and the second touch routing line TL(2) are disposed adjacent to each other, as the first single line portion of the first touch routing line TL(1) and the second single line portion of the second touch routing line TL(2) are disposed on different metal layers, therefore, the first single line portion of the first touch routing line TL(1) and the second single line portion of the second touch routing line TL(2) can be spaced apart in a diagonal direction. According to this configuration, a coupling capacitance (coupling noise) between the plurality of touch routing lines TL in the first non-display area NDA1 can be reduced. Therefore, the quality of touch driving and touch sensing through a plurality of touch routing lines TL can be improved.

Referring to FIGS. 7, 9, and 10, in the first touch routing line TL(1), a line width DW1 of the first double line portion TL(1)_7 may be greater than a line width SW of the first single line portion (TL(1)_4, TL(1)_5, and TL(1)_6). In the second touch routing line TL(2), a line width DW2 of the second double line portion TL(2)_7 may be greater than a line width SW of the second single line portion (TL(2)_4, TL(2)_5, and TL(2)_6).

Referring to FIG. 8, the first double line portion TL(1)_7 of the first touch routing line TL(1) may have a line width DW1 greater than a line width DW2 of the second double line portion TL(2)_7 of the second touch routing line TL(2).

Referring to FIG. 7, the nth single line portion (TL(n)_4, TL(n)_5, TL(n)_6, and TL(n)_7) of the nth touch routing line TL(n) may overlap with a common electrode CE to which a first common voltage VSS is applied.

In an area where the nth single line portion (TL(n)_4, TL(n)_5, TL(n)_6, and TL(n)_7) of the nth touch routing line TL(n) is disposed, at least one signal line may be disposed such that the at least one signal line overlaps with the nth single line portion (TL(n)_4, TL(n)_5, TL(n)_6, and TL(n)_7) of the nth touch routing line TL(n) and delivers at least one signal different from the first common voltage VSS applied to the common electrode CE. For example, the at least one signal line may include at least one of a second common voltage line VDDL to which a second common voltage VDD is applied, and a gate driving-related signal line to which a gate driving-related signal is applied. For example, the at least one gate driving-related signals may include at least one of a gate clock signal, a high-level gate voltage, a low-level gate voltage, a gate driving power supply voltage, and the like.

In one or more aspects, the common electrode CE may be disposed to extend between the nth single line portion (TL(n)_4, TL(n)_5, TL(n)_6, and TL(n)_7) of the nth touch routing line TL(n) and the at least one signal line. For example, the nth single line portion (TL(n)_4, TL(n)_5, TL(n)_6, and TL(n)_7) of the nth touch routing line TL(n), the common electrode CE, and the at least one signal line may overlap with each other in the vertical direction.

Accordingly, undesired capacitance can be prevented or reduced from being formed between the nth single line portion (TL(n)_4, TL(n)_5, TL(n)_6, and TL(n)_7) of the nth touch routing line TL(n) and the at least one signal line.

In contrast, the first single line portion (TL(1)_4, TL(1)_5, and TL(1)_6) of the first touch routing line TL(1) may not overlap with the common electrode CE. However, at least a portion of the first double line portion TL(1)_7 of the first touch routing line TL(1) may overlap with the common electrode CE and also overlap with at least one of a plurality of signal lines (SL1, SL2, SL3, and SL4).

At least one of the plurality of signal lines (SL1, SL2, SL3, and SL4) may not be disposed under the first single line portion (TL(1)_4, TL(1)_5, and TL(1)_6) of the first touch routing line TL(1). Accordingly, the common electrode CE may not be needed to extend under the first single line portion (TL(1)_4, TL(1)_5, and TL(1)_6) of the first touch routing line TL(1).

Referring to FIG. 7, the non-display area NDA may include the first non-display area NDA1 located adjacent to the display area DA, the second non-display area NDA2 including the pad area PA on which a plurality of touch pads are disposed, and the bending area BA between the first non-display area NDA1 and the second non-display area NDA2.

Referring to FIG. 7, each of the n touch routing lines (TL(1) to TL(n)) may include a first portion (TL(1)_3 to TL(1)_7, TL(2)_3 to TL(2)_7, and TL(n)_3 to TL(n)_7) located in the first non-display area NDA1, a second portion (TL(1)_1, TL(2)_1, and TL(n)_1) located in the second non-display area NDA2, and a third portion (TL(1)_2 to TL(1)_3, TL(2)_2 to TL(2)_3, and TL(n)_2 to TL(n)_3) located in the bending area BA.

Referring to FIG. 7, the first single line portion (TL(1)_4, TL(1)_5, and TL(1)_6) and the first double line portion TL(1)_7 of the first touch routing line TL(1) may be included in the first portion (TL(1)_3 to TL(1)_7) of the first touch routing line TL(1).

For example, the first single line portion (TL(1)_4, TL(1)_5, and TL(1)_6) of the first touch routing line TL(1) may be disposed in an area adjacent to the bending area BA (e.g., an upper edge over, or a lower edge under, the display area DA) among areas of the first non-display area NDA1 and be disposed in the first direction (e.g., the row direction).

For example, the first double line portion TL(1)_7 of the first touch routing line TL(1) may be disposed in at least one area on at least one of left and right sides of the display area DA among areas of the first non-display area NDA1, and be disposed in the second direction (e.g., the column direction) different from the first direction.

Referring to FIG. 7, the second portion TL(n)_1 of the nth touch routing line TL(n) may have a length longer than the second portion TL(1)_1 of the first touch routing line TL(1). For example, the second portion TL(n)_1 of the nth touch routing line TL(n) may have a curved shape.

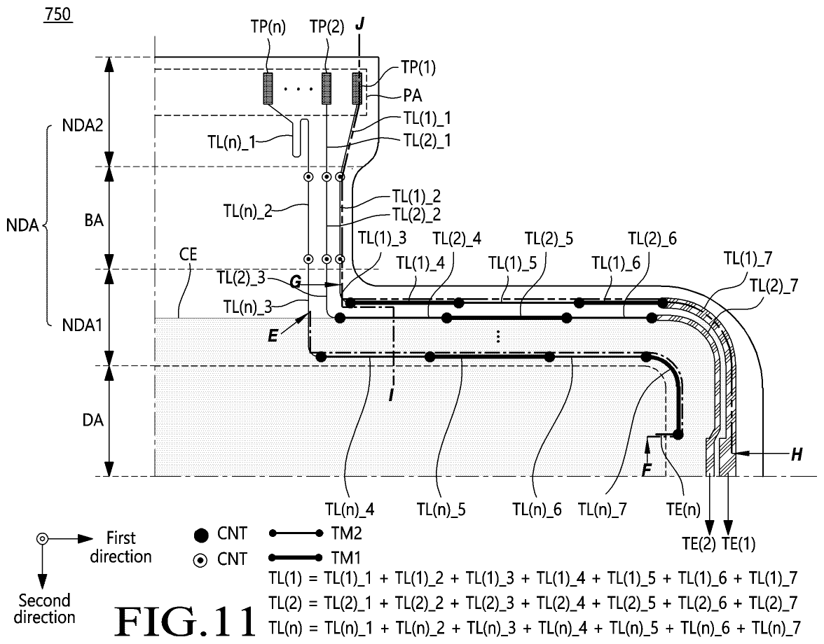

FIGS. 11 to 14 illustrate example touch routing line structures in the display panel 110 according to embodiments of the present disclosure.

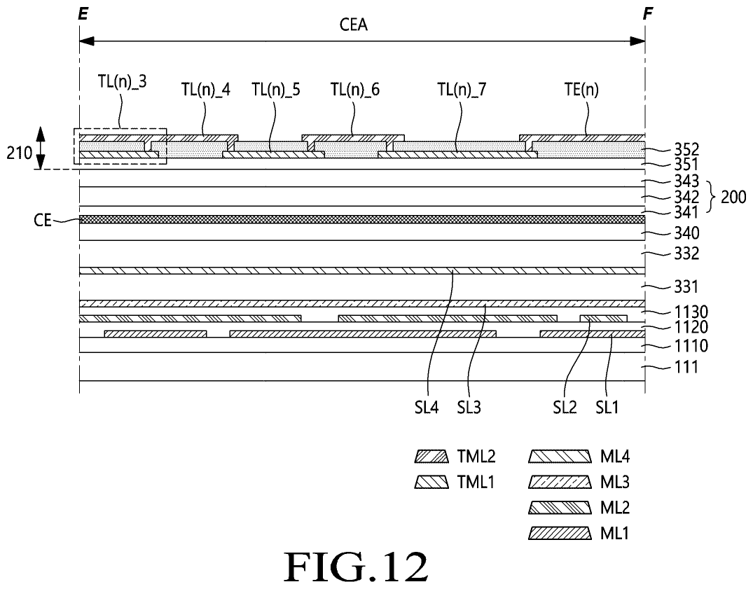

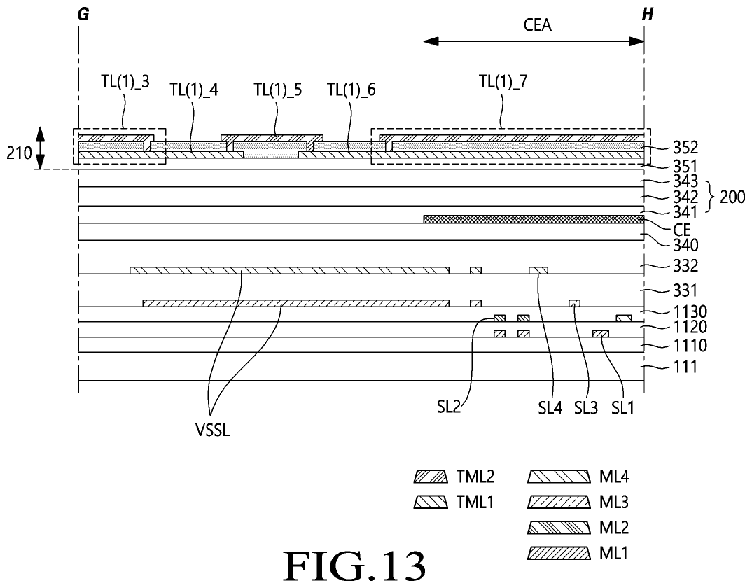

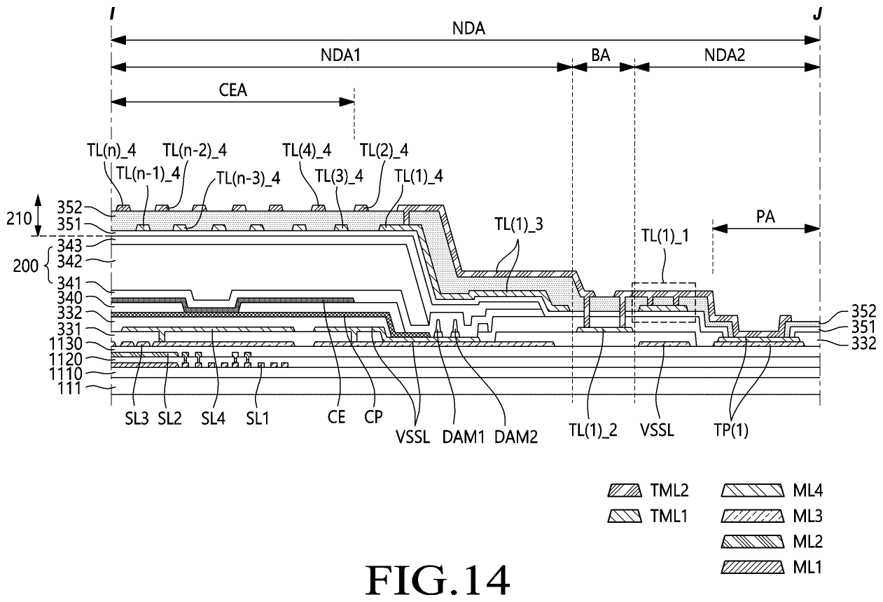

FIG. 11 is an enlarged plan view of a partial area 750 of FIG. 7 according to embodiments of the present disclosure. FIG. 12 is a cross-sectional view taken along line E-F of FIG. 11 according to embodiments of the present disclosure. FIG. 13 is a cross-sectional view taken along line G-H of FIG. 11 according to embodiments of the present disclosure. FIG. 14 is a cross-sectional view taken along line I-J of FIG. 11 according to embodiments of the present disclosure.

Referring to FIG. 11, line E-F is a line connecting portions (TL(n)_3 to TL(n)_7) of the nth touch routing line TL(n) and an nth touch electrode TE(n), the line G-H is a line connecting portions (TL(1)_3 to TL(1)_7) of the first touch routing line TL(1), and line I-J is a line connecting the first touch pad TP(1) and portions (TL(1)_1 to TL(1)_3) of the first touch routing line TL(1), and connecting in a crosswise direction some single line portions (TL(1)_4, TL(2)_4, . . . , TL(n)_4) of the first to nth touch routing lines (TL(1) to TL(n)).

Referring to FIGS. 11 and 12, in one or more example embodiments, the display panel 110 may include the substrate 111 including the display area DA and the non-display area NDA adjacent to the display area DA, a common electrode CE disposed on the substrate 111 and allowing a first common voltage VSS for display driving to be applied, at least one signal line (SL1, SL2, SL3, and/or SL4) disposed on the substrate 111 and delivering a signal different from the first common voltage VSS, a plurality of touch electrodes (TE(1) to TE(n)) located in the display area DA and disposed on the common electrode CE, and a plurality of touch routing lines (TL(1) to TL(n)) electrically connected to the plurality of touch electrodes (TE(1) to TE(n)).

Referring to FIG. 11, each of n touch routing lines (TL(1) to TL(n)) may include first portions (TL(1)_3 to TL(1)_7, TL(2)_3 to TL(2)_7, and TL(n)_3 to TL(n)_7) located in the first non-display area NDA1, second portions (TL(1)_1, TL(2)_1, and TL(n)_1) located in the second non-display area NDA2, and third portions (TL(1)_2 to TL(1)_3, TL(2)_2 to TL(2)_3, and TL(n)_2 to TL(n)_3) located in the bending area BA.

Referring to FIG. 11, the third portions (TL(1)_2 to TL(1)_3, TL(2)_2 to TL(2)_3, and TL(n)_2 to TL(n)_3) located in the bending area BA may include a metal not included in the first portion (TL(1)_3 to TL(1)_7, TL(2)_3 to TL(2)_7, and TL(n)_3 to TL(n)_7).

Referring to FIGS. 12 to 14, stack-up configurations of the display panel 110 may be substantially the same as the stack-up configurations of the display panel 110 of FIG. 3. Stack-up configurations of FIGS. 12 to 14 will be briefly described below.

Referring to FIGS. 12 to 14, a first insulating layer 1110 may be disposed on the substrate 111, a second insulating layer 1120 may be disposed on the first insulating layer 1110, and a third insulating layer 1130 may be disposed on the second insulating layer 1120.

For example, the first insulating layer 1110 may include the first buffer layer 311 and the first gate insulating layer 312 of FIG. 3. The second insulating layer 1120 may include the first interlayer insulating layer 313 of FIG. 3. The third insulating layer 1130 may include the second buffer layer 321, the second gate insulating layer 322, and the second interlayer insulating layer 323 of FIG. 3.

Referring to FIGS. 12 to 14, a first planarization layer 331 may be disposed on the third insulating layer 1130. A second planarization layer 332 may be disposed on the first planarization layer 331. A bank 340 may be disposed on the second planarization layer 332.

The common electrode CE may be disposed on the bank 340. The encapsulation layer 200 may be disposed on the common electrode CE, and the encapsulation layer 200 may include the first encapsulation layer 341, the second encapsulation layer 342, and the third encapsulation layer 343.

Referring to FIGS. 12 to 14, a touch sensor layer 210 may be disposed on the encapsulation layer 200. The touch sensor layer 210 may include a touch buffer layer 351 on the encapsulation layer 200, a first touch metal layer TML1 on the touch buffer layer 351, a touch interlayer insulating layer 352 on the first touch metal layer TML1, and a second touch metal layer TML2 on the touch interlayer insulating layer 352.

Referring to FIGS. 12 to 14, in one or more embodiments, the display panel 110 may include a first metal layer ML1 disposed between the first insulating layer 1110 and the second insulating layer 1120, a second metal layer ML2 disposed between the second insulating layer 1120 and the third insulating layer 1130, a third metal layer ML3 disposed between the third insulating layer 1130 and the first planarization layer 331, and a fourth metal layer ML4 disposed between the first planarization layer 331 and the second planarization layer 332.

For example, the fourth metal layer ML4 may be a second source-drain metal layer. The third metal layer ML3 may be a first source-drain metal layer. The second metal layer ML2 may be a metal layer in which a second capacitor electrode CAPE2 is disposed. The first metal layer ML1 may be a first gate metal layer.

Transistors, capacitors, and several signal lines included in the display panel 110 may be disposed in at least one metal layer among the first to fourth metal layers (ML1, ML2, ML3, and ML4).

For example, a plurality of signal lines to which signals different from a common voltage VSS are applied may be disposed in at least one metal layer among the first to fourth metal layers (ML1, ML2, ML3, and ML4). For example, the plurality of signal lines may be lines for delivering signals related to display driving. For example, the plurality of signal lines may include at least one of at least one second common voltage line VDDL for delivering a second common voltage VDD, at least one data line DL for delivering a data signal VDATA, at least one gate line GL for delivering a gate signal, and at least one gate driving-related signal line for delivering several gate driving-related signals supplied to the gate driving circuit 130. For example, the at least one gate driving-related signals may include at least one of a gate clock signal, a high-level gate voltage, a low-level gate voltage, a gate driving power supply voltage, and the like.

Referring to FIGS. 12 to 14, the common electrode CE may be disposed in the display area DA, and in one or more aspects, be extended to a portion of the first non-display area NDA1. For example, a common electrode arrangement area CEA where the common electrode CE is disposed may include the display area DA and a portion of the first non-display area NDA1.

Referring to FIGS. 12 to 14, at least a portion of at least one of the n touch routing lines TL may overlap with the common electrode CE.

Referring to FIG. 12, among the plurality of touch routing lines (TL(1) to TL(n)), an nth touch routing line TL(n) may overlap with the at least one signal line (SL1, SL2, SL3, and/or SL4).

The common electrode CE may be disposed between the nth touch routing line TL(n) and the at least one signal line (SL1, SL2, SL3, and/or SL4). The common electrode CE may extend under the nth touch routing line TL(n) overlapping with the at least one signal line (SL1, SL2, SL3, and/or SL4).

Accordingly, the formation of coupling capacitance (coupling noise) between the nth touch routing line TL(n) and the at least one signal line (SL1, SL2, SL3, and/or SL4) can be prevented or reduced. The formation of coupling capacitance (coupling noise) between the nth touch routing line TL(n) and the at least one signal line (SL1, SL2, SL3, and/or SL4) may mean that a change in voltage on the at least one signal line (SL1, SL2, SL3, and/or SL4) may cause an undesired change in voltage on the nth touch routing line TL(n).

Accordingly, as the common electrode CE is disposed to extend between the at least one signal line (SL1, SL2, SL3, and/or SL4) and the nth touch routing line TL(n), the common electrode CE can reduce or block a bad influence (i.e., display noise) on the nth touch routing line TL(n) by driving (e.g., a resulted change in voltage) at least one signal line (SL1, SL2, SL3, and/or SL4).

Referring to FIG. 13, among the plurality of touch routing lines (TL(1) to TL(n)), a first touch routing line TL(1) may include at least a portion not overlapping with the at least one signal line (SL1, SL2, SL3, and/or SL4). For example, the at least one signal line (SL1, SL2, SL3, and/or SL4) may not be disposed under the at least a portion of the first touch routing line TL(1).

As described above, since the at least one signal line (SL1, SL2, SL3, and/or SL4) is not disposed under at least a portion of the first touch routing line TL(1), the common electrode CE may not extend under the at least a portion of the first touch routing line TL(1). For example, the at least a portion of the first touch routing line TL(1) may not overlap with the common electrode CE.

For example, at least a portion of the first touch routing line TL(1) not overlapping with the at least one signal line (SL1, SL2, SL3, and/or SL4) may include a first single line portion (TL(1)_4 to TL(1)_6) of the first touch routing line TL(1).

For example, the at least a portion of the first touch routing line TL(1) not overlapping with the common electrode CE may include the first single line portion (TL(1)_4 to TL(1)_6) of the first touch routing line TL(1).

Referring to FIG. 13, at least another portion included in the first touch routing line TL(1) may overlap with the common electrode CE and also overlap with the at least one signal line (SL1, SL2, SL3, and/or SL4).

The common electrode CE may be disposed to extend between the at least another portion of the first touch routing line TL(1) and the at least one signal line (SL1, SL2, SL3, and/or SL4).

For example, the at least another portion of the first touch routing line TL(1) overlapping with the common electrode CE may include a first double line portion TL(1)_7 of the first touch routing line TL(1). The at least another portion of the first touch routing line TL(1) overlapping with the at least one signal line (SL1, SL2, SL3, and/or SL4) may include the first double line portion TL(1)_7 of the first touch routing line TL(1).

Referring to FIGS. 11 and 12, an nth single line portion (TL(n)_4, TL(n)_5, TL(n)_6, and TL(n)_7) of the nth touch routing line TL(n) may overlap with the common electrode CE.

A portion of the nth touch routing line TL(n) overlapping with the common electrode CE may include the nth single line portion (TL(n)_4, TL(n)_5, TL(n)_6, and TL(n)_7) in which the first touch metal layer TML1 and the second touch metal layer TML2 are alternately disposed.

At least a portion of the nth single line portion (TL(n)_4, TL(n)_5, TL(n)_6, and TL(n)_7) of the nth touch routing line TL(n) may overlap with the common electrode CE and overlap with at least one of the plurality of signal lines (SL1, SL2, SL3, and/or SL4).

The common electrode CE may be disposed between the at least one of the plurality of signal lines (SL1, SL2, SL3, and/or SL4) and the nth single line portion (TL(n)_4, TL(n)_5, TL(n)_6, and TL(n)_7) of the nth touch routing line TL(n).

Referring to FIG. 11 and FIG. 13, a portion of the first touch routing line TL(1) overlapping with the common electrode CE may include the first double line portion TL(1)_7 in which the first touch metal layer TML1 and the second touch metal layer TML2 overlap with each other and are electrically connected to each other, and a portion of the first touch routing line TL(1) not overlapping with the common electrode CE may include the first single line portion (TL(1)_4 to TL(1)_6) in which the first touch metal layer TML1 and the second touch metal layer TML2 are alternately disposed.

The first single line portion (TL(1)_4, TL(1)_5, TL(1)_6) of the first touch routing line TL(1) may not overlap with the common electrode CE. The first double line portion TL(1)_7 of the first touch routing line TL(1) may overlap with the common electrode CE.

At least a portion of the first double line portion TL(1)_7 of the first touch routing line TL(1) may overlap with the common electrode CE and also overlap with at least one of the plurality of signal lines (SL1, SL2, SL3, and/or SL4). The common electrode CE may be disposed between at least one of the plurality of signal lines (SL1, SL2, SL3, and/or SL4) and the first double line portion TL(1)_7 of the first touch routing line TL(1).

Referring to FIGS. 13 and 14, in one or more aspects, the display panel 110 may further include a first common voltage line VSSL to which a first common voltage VSS is applied.

The first single line portion (TL(1)_4, TL(1)_5, and TL(1)_6) of the first touch routing line TL(1) may not overlap with the common electrode CE and the at least one signal line (SL1, SL2, SL3, and/or SL4). The first single line portion (TL(1)_4, TL(1)_5, and TL(1)_6) of the first touch routing line TL(1) may overlap with the first common voltage line VSSL to which the first common voltage VSS is applied.

As described above, the display panel 110 may include a pixel electrode PE disposed over the substrate 111 and located in the display area DA, an intermediate layer EL disposed on the pixel electrode PE, the common electrode CE disposed on the intermediate layer EL and allowing the first common voltage VSS to be applied, the encapsulation layer 200 disposed on the common electrode CE, and a plurality of touch electrodes TE disposed on the encapsulation layer 200.

Referring to FIG. 14, the non-display area NDA may include the first non-display area NDA1, the bending area BA, and the second non-display area NDA2.

The common electrode CE may be disposed to extend from the display area DA to a portion of the first non-display area NDA1.

The encapsulation layer 200 may be disposed to extend further outward than the common electrode CE. For example, the encapsulation layer 200 may extend from the display area DA to the first non-display area NDA1, and further extend to a boundary between the first non-display area NDA1 and the bending area BA.

A first dam DAM1 and a second dam DAM2 may be disposed adjacent to an edge of a second encapsulation layer 342 included in the encapsulation layer 200. The first dam DAM1 and the second dam DAM2 may prevent or reduce the second encapsulation layer 342 including an organic material from overflowing.

The touch buffer layer 351 may be disposed to extend from the display area DA to the non-display area NDA, and have an opening for exposing at least a portion of a touch pad TP(1) in the pad area PA.

The touch interlayer insulating layer 352 may be disposed to extend from the display area DA to the non-display area NDA, and have an opening for exposing the at least a portion of the touch pad TP(1) in the pad area PA.

Referring to FIG. 11 and FIG. 14, single line portions (TL(n)_4, TL(n−1)_4, TL(n−2)_4, TL(n−3)_4, . . . , TL(4)_4, TL(3)_4, TL(2)_4, TL(1)_4), which are respective first portions of n touch routing lines (TL(1) to TL(n)), may be disposed in the first non-display area NDA1.

Referring to FIGS. 11 and 14, the single line portions (TL(n)_4, TL(n−1)_4, TL(n−2)_4, TL(n−3)_4, . . . , TL(4)_4, TL(3)_4, TL(2)_4, TL(1)_4), which are respective first portions of the n touch routing lines (TL(1) to TL(n)), may be disposed in the first touch metal layer TML1 and the second touch metal layer TML2.

Referring to FIGS. 11 and 14, when single line portions of two adjacent touch routing lines among the n touch routing lines (TL(1) to TL(n)) are adjacent to each other in the second direction, one of the two single line portions adjacent to each other in the second direction may be disposed in the first touch metal layer TML1, and the other thereof may be disposed in the second touch metal layer TML2.

Referring to FIGS. 11 and 14, the first touch routing line TL(1) may extend along an upper surface and an inclined surface of the encapsulation layer 200.

For example, a portion (TL(1)_3) of the first touch routing line TL(1) disposed on the inclined surface of the encapsulation layer 200 may have a double line structure. The double line portion TL(1)_3 disposed on the inclined surface of the encapsulation layer 200 may be configured with an electrical connection of a lower portion disposed in the first touch metal layer TML1 and an upper portion disposed in the second touch metal layer TML2.

Referring to FIG. 11 and FIG. 14, in the bending area BA, the first touch routing line TL(1) may be disposed in a fourth metal layer ML4 different from the first touch metal layer TML1 and the second touch metal layer TML2. For example, the first touch routing line TL(1) may include a third portion TL(1)_2 disposed in the bending area BA, and the third portion TL(1)_2 of the first touch routing line TL(1) disposed in the bending area BA may be disposed in a fourth metal layer ML4 different from the first touch metal layer TML1 and the second touch metal layer TML2. For example, the third portion TL(1)_2 of the first touch routing line TL(1) disposed in the bending area BA may be disposed in the fourth metal layer ML4. For example, the fourth metal layer ML4 may be a second source-drain metal layer.

Referring to FIGS. 11 and 14, in the second non-display area NDA2, the first touch routing line TL(1) may be disposed in at least one touch metal layer among the first touch metal layer TML1 and the second touch metal layer TML2. For example, a second portion TL(1)_1 of the first touch routing line TL(1) disposed in the second non-display area NDA2 may be disposed in at least one touch metal layer among the first touch metal layer TML1 and the second touch metal layer TML2.

Referring to FIG. 11 and FIG. 14, the second portion TL(1)_1 of the first touch routing line TL(1) disposed in the second non-display area NDA2 may be electrically connected to the first touch pad TP(1) disposed in the pad area PA. For example, the first touch pad TP(1) may be disposed in at least one of the third metal layer ML3 and the fourth metal layer ML4. For example, the third metal layer ML3 may be a first source-drain metal layer, and the fourth metal layer ML4 may be a second source-drain metal layer.

Referring to FIG. 14, in one or more embodiments, in the non-display area NDA of the display panel 110, the common electrode CE may be electrically connected to the first common voltage line VSSL. The first common voltage line VSSL may be disposed in at least one of the third metal layer ML3 and the fourth metal layer ML4.

Referring to FIG. 14, the common electrode CE may be electrically connected to the first common voltage line VSSL through a connection pattern CP. For example, the connection pattern CP may include the same material as the pixel electrode PE and be disposed in the same layer as the pixel electrode PE.

Referring to FIG. 14, the first common voltage line VSSL may run under at least one dam (DAM1 and/or DAM2). At least a portion of the first common voltage line VSSL may overlap with the at least one dam (DAM1 and/or DAM2).

The examples, aspects, and embodiments described above will be briefly described as follows.

According to the one or more example embodiments described herein, a display device can be provided that includes a substrate including a display area and a non-display area adjacent to the display area, n touch electrodes disposed on the substrate and located in the display area, where n is a natural number greater than or equal to 2, n touch pads disposed on the substrate and located in the non-display area, and n touch routing lines disposed on the substrate, electrically interconnecting the n touch electrodes and the n touch pads, and disposed in a portion of an outer edge of the display area.

In one or more embodiments, the n touch routing lines may include a first touch routing line for electrically connecting a first touch electrode among the n touch electrodes to a first touch pad among the n touch pads, and an nth touch routing line for electrically connecting an nth touch electrode among the n touch electrodes to an nth touch pad among the n touch pads.

In one or more embodiments, the first touch routing line may include a first single line portion and a first double line portion that are electrically connected to each other. In one or more aspects, the first single line portion may be electrically connected to the first touch electrode through the first double line portion.

In one or more embodiments, the nth touch routing line may be disposed closer to the display area than the first touch routing line.

In one or more embodiments, the first double line portion may be located further away from the first touch pad than the first single line portion.

In one or more embodiments, the display device may further include a plurality of subpixels disposed on the substrate and located in the display area, a plurality of gate lines disposed on the substrate, delivering gate signals to the plurality of subpixels, and extending in a first direction, and a plurality of data lines disposed on the substrate, delivering data signals to the plurality of subpixels, and extending in a second direction different from the first direction.

In one or more embodiments, the first single line portion may extend in the first direction.

In one or more embodiments, the first single line portion may include a first lower metal portion disposed in a first touch metal layer, and a first upper metal portion disposed in a second touch metal layer different from the first touch metal layer.

In one or more embodiments, the first lower metal portion and the first upper metal portion may be disposed alternately.

In one or more embodiments, the first double line portion may include the first touch metal layer and the second touch metal layer that overlap with each other and are electrically connected to each other.

In one or more embodiments, the n touch routing lines may further include a second touch routing line electrically interconnecting a second touch electrode among the n touch electrodes and a second touch pad among the n touch pads.

In one or more embodiments, the second touch routing line may include a second single line portion and a second double line portion. In one or more aspects, the second single line portion and the second double line portion may be electrically connected to each other.

In one or more embodiments, the second single line portion may be electrically connected to the second touch electrode through the second double line portion.

In one or more embodiments, the second single line portion may include a second lower metal portion disposed in the first touch metal layer and a second upper metal portion disposed in the second touch metal layer. In one or more aspects, the second lower metal portion and the second upper metal portion may be disposed alternately.

In one or more embodiments, the second double line portion may include the first touch metal layer and the second touch metal layer that overlap each other and are electrically connected to each other.

In one or more embodiments, the second touch routing line may be disposed adjacent to the first touch routing line and be disposed closer to the display area than the first touch routing line.

In one or more embodiments, the first lower metal portion may be disposed adjacent to the second upper metal portion. In one or more aspects, the first upper metal portion may be disposed adjacent to the second lower metal portion.

In one or more embodiments, the first double line portion may have a line width greater than the second double line portion.

In one or more embodiments, the display device may further include a pixel electrode disposed on the substrate and located in the display area, an intermediate layer disposed on the pixel electrode, a common electrode disposed on the intermediate layer and allowing a first common voltage to be applied, and an encapsulation layer disposed on the common electrode.

In one or more embodiments, the plurality of touch electrodes may be disposed on the encapsulation layer.

In one or more embodiments, the encapsulation layer may extend further outward than the common electrode.

In one or more embodiments, at least a portion of at least one of the n touch routing lines may overlap with the common electrode.

In one or more embodiments, wherein the nth touch routing line may include an nth single line portion electrically connected to the nth touch electrode.

In one or more embodiments, the nth single line portion may overlap with the common electrode.

In one or more embodiments, the display device may further include a plurality of signal lines to which signals different from the first common voltage are applied.

In one or more embodiments, at least a portion of the nth touch routing line may overlap with the common electrode and overlap with at least one of the plurality of signal lines, and the common electrode may extend between the at least one signal line and the at least a portion of the nth touch routing line.

In one or more embodiments, at least a portion of the nth single line portion may overlap with the common electrode and overlap with at least one of the plurality of signal lines.

In one or more embodiments, the common electrode may extend between at least one of the plurality of signal lines and the nth single line portion.

In one or more embodiments, the first single line portion may not overlap with the common electrode.

In one or more embodiments, at least a portion of the first double line portion may overlap with the common electrode and overlap with at least one of the plurality of signal lines.

In one or more embodiments, the common electrode may extend between the at least one signal line and the first double line portion.

In one or more embodiments, the display device may further include a first common voltage line to which the first common voltage is applied. In one or more aspects, the first single line portion may overlap with the first common voltage line to which the first common voltage is applied.

In one or more embodiments, the non-display area may include a first non-display area located adjacent to the display area, a second non-display area comprising a pad area where the plurality of touch pads are disposed, and a bending area between the first non-display area and the second non-display area.

In one or more embodiments, each of the n touch routing lines may include a first portion located in the first non-display area, a second portion located in the second non-display area, and a third portion located in the bending area.

In one or more embodiments, the first single line portion and the first double line portion may be included in the first portion.

In one or more embodiments, the first single line portion may be disposed in an area adjacent to the bending area among areas of the first non-display area, and disposed in a first direction. In one or more aspects, the first double line portion may be disposed in at least one area on at least one of left and right sides of the display area among the areas of the first non-display area, and disposed in a second direction different from the first direction.

In one or more embodiments, the second portion of the nth touch routing line may have a length longer than the second portion of the first touch routing line, and the second portion of the nth touch routing line may have a curved shape.

In one or more embodiments, the third portion may include a metal not included in the first portion.

In one or more embodiments, the display device may further include a ground line disposed between two of the n touch routing lines. In one or more aspects, the ground line may include a touch metal included in n touch routing lines.

According to the one or more example embodiments described herein, a display device can be provided that includes a substrate including a display area and a non-display area adjacent to the display area, a common electrode disposed over the substrate and allowing a first common voltage for display driving to be applied, a signal line disposed on the substrate and delivering a signal different from the first common voltage, a plurality of touch electrodes located in the display area and disposed on the common electrode, and a plurality of touch routing lines electrically connected to the plurality of touch electrodes.

In one or more embodiments, the plurality of touch routing lines may include a first touch routing line including at least a portion not overlapping with the signal line, and an nth touch routing line overlapping with the signal line.

In one or more embodiments, the common electrode may not extend under at least a portion of the first touch routing line, but may extend under the nth touch routing line.

In one or more embodiments, a portion of the nth touch routing line overlapping with the common electrode may include a single line portion in which a first touch metal layer and a second touch metal layer are alternately disposed.

In one or more embodiments, a portion of the first touch routing line not overlapping with the common electrode may include a single line portion in which the first touch metal layer and the second touch metal layer are alternately disposed, and another portion of the first touch routing line overlapping with the common electrode may include a double line portion in which the first touch metal layer and the second touch metal layer overlap with each other and are electrically connected to each other.

According to the one or more embodiments described herein, a display device may be provided that includes a touch routing line structure capable of reducing a size of a non-display area (bezel) in which a plurality of touch routing lines are disposed.

According to the one or more embodiments described herein, a display device may be provided that includes a touch routing line structure capable of improving the quality of touch driving and touch sensing.

According to the one or more embodiments described herein, a display device may be provided that includes a touch routing line structure capable of reducing coupling noise between touch channels.

According to the one or more embodiments described herein, a display device may be provided that includes a touch routing line structure capable of reducing a difference in resistance between touch channels.

According to the one or more embodiments described herein, a display device may be provided that includes touch routing lines disposed in a structure of being robust to display noise.

According to the one or more embodiments described herein, a display device may be provided that is capable of reducing the size of a bezel of the display device, and thereby, capable of meeting size requirements on the design of the display device and helping the display device be lighter.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate comprising a display area and a non-display area adjacent to the display area;
n touch electrodes on the substrate and located in the display area, where n is a natural number greater than or equal to 2;
n touch pads on the substrate and located in the non-display area; and
n touch routing lines on the substrate, the n touch routing lines electrically interconnecting the n touch electrodes and the n touch pads, and the n touch routing lines in a portion of an outer edge of the display area,
wherein the n touch routing lines comprise a first touch routing line and an n^{th} touch routing line, the first touch routing line electrically interconnecting a first touch electrode among the n touch electrodes and a first touch pad among the n touch pads, and the n^{th} touch routing line electrically interconnecting an n^{th} touch electrode among the n touch electrodes and an n^{th} touch pad among the n touch pads, and
wherein the first touch routing line comprises a first single line portion and a first double line portion, the first single line portion and the first double line portion are electrically connected to each other, and the first single line portion is electrically connected to the first touch electrode through the first double line portion.

2. The display device of claim 1, wherein the n^{th} touch routing line is closer to the display area than the first touch routing line.

3. The display device of claim 1, wherein the first double line portion is located farther away from the first touch pad than the first single line portion.

4. The display device of claim 1, further comprising:
a plurality of subpixels on the substrate, the plurality of subpixels located in the display area;
a plurality of gate lines on the substrate, the plurality of gate lines delivering gate signals to the plurality of subpixels and the plurality of gate lines extending in a first direction; and
a plurality of data lines on the substrate, the plurality of data lines delivering data signals to the plurality of subpixels and the plurality of data lines extending in a second direction different from the first direction, and
wherein the first single line portion extends in the first direction.

5. The display device of claim 1, wherein the first single line portion comprises a first lower metal portion and a first upper metal portion, the first lower metal portion in a first touch metal layer and the first upper metal portion in a second touch metal layer different from the first touch metal layer, and the first lower metal portion and the first upper metal portion are disposed alternately, and
wherein the first double line portion comprises the first touch metal layer and the second touch metal layer, the first touch metal layer and the second touch metal layer overlap with each other and are electrically connected to each other.

6. The display device of claim 5, wherein the n touch routing lines further comprise:
a second touch routing line electrically interconnecting a second touch electrode among the n touch electrodes and a second touch pad among the n touch pads,
wherein the second touch routing line comprises a second single line portion and a second double line portion, the second single line portion and the second double line portion electrically connected to each other, and the second single line portion is electrically connected to the second touch electrode through the second double line portion, and
wherein the second single line portion comprises a second lower metal portion and a second upper metal portion, the second lower metal portion in the first touch metal layer and the second upper metal portion in the second touch metal layer, and the second lower metal portion and the second upper metal portion are disposed alternately,
wherein the second double line portion comprises the first touch metal layer and the second touch metal layer, the first touch metal layer and the second touch metal layer overlap each other and are electrically connected to each other, and
wherein the second touch routing line is adjacent to the first touch routing line and the second touch routing line is closer to the display area than the first touch routing line.

7. The display device of claim 6, wherein the first lower metal portion is adjacent to the second upper metal portion and the first upper metal portion is adjacent to the second lower metal portion.

8. The display device of claim 6, wherein the first double line portion has a line width that is greater than a line width of the second double line portion.

9. The display device of claim 1, further comprising:
a pixel electrode on the substrate, the pixel electrode located in the display area;
an intermediate layer on the pixel electrode;
a common electrode on the intermediate layer, wherein a first common voltage is applied to the common electrode; and
an encapsulation layer on the common electrode,
wherein the n touch electrodes are on the encapsulation layer, and
wherein the encapsulation layer extends farther outward than the common electrode and at least a portion of at least one of the n touch routing lines overlaps with the common electrode.

10. The display device of claim 9, wherein the n^{th} touch routing line comprises an nth single line portion electrically connected to the n^{th} touch electrode and the n^{th} single line portion overlaps with the common electrode.

11. The display device of claim 9, further comprising:
a plurality of signal lines, wherein signals different from the first common voltage are applied to the plurality of signal lines,
wherein at least a portion of the n^{th} touch routing line overlaps with the common electrode and the at least the portion of the n^{th} touch routing line overlaps with at least one of the plurality of signal lines, and
wherein the common electrode extends between the at least one signal line and the at least the portion of the n^{th} touch routing line.

12. The display device of claim 9, wherein the first single line portion is non-overlapping with the common electrode.

13. The display device of claim 12, further comprising:
a plurality of signal lines, wherein signals different from the first common voltage are applied to the plurality of signal lines,
wherein at least a portion of the first double line portion overlaps with the common electrode and at least the portion of the first double line portion overlaps with at least one of the plurality of signal lines, and the common electrode extends between the at least one of the plurality of signal lines and the first double line portion.

14. The display device of claim 12, further comprising:
a first common voltage line, wherein the first common voltage is applied to the first common voltage line,
wherein the first single line portion overlaps with the first common voltage line, the first common voltage is applied to the first common voltage line.

15. The display device of claim 1, wherein the non-display area comprises a first non-display area, a second non-display area, and a bending area, the first non-display area located adjacent to the display area, the second non-display area comprising a pad area where the n touch pads are disposed, and the bending area between the first non-display area and the second non-display area,
wherein each of the n touch routing lines comprises a first portion located in the first non-display area, a second portion located in the second non-display area, and a third portion located in the bending area,
wherein the first single line portion and the first double line portion are included in the first portion, and
wherein the first single line portion is in an area adjacent to the bending area among areas of the first non-display area and the first single line portion is disposed in a first direction, and the first double line portion is in at least one area on at least one of a left side and a right side of the display area among the areas of the first non-display area and the first double line portion is disposed in a second direction different from the first direction.

16. The display device of claim 15, wherein the second portion of the n^{th} touch routing line has a length that is longer than a length the second portion of the first touch routing line, and the second portion of the n^{th} touch routing line has a curved shape.

17. The display device of claim 15, wherein the third portion comprises a metal that is not included in the first portion.

18. The display device of claim 15, further comprising:
a ground line between two of the n touch routing lines.

19. A display device comprising:
a substrate comprising a display area and a non-display area adjacent to the display area;
a common electrode over the substrate, wherein a first common voltage for display driving is applied to the common electrode;
a signal line on the substrate, the signal line delivering a signal different from the first common voltage;
a plurality of touch electrodes located in the display area, the plurality of touch electrodes on the common electrode; and
a plurality of touch routing lines electrically connected to the plurality of touch electrodes, wherein the plurality of touch routing lines comprise a first touch routing line and an nth touch routing line, the first touch routing line comprising at least a portion that nis non-overlapping with the signal line, and the n^{th} touch routing line overlapping with the signal line, and
wherein the common electrode extends under the n^{th} touch routing line without the common electrode extending under the at least a portion of the first touch routing line.

20. The display device of claim 19, wherein a portion of the n^{th} touch routing line overlapping with the common electrode comprises a single line portion, a first touch metal layer and a second touch metal layer are alternately disposed in the single line portion, and
wherein a portion of the first touch routing line that is non-overlapping with the common electrode comprises a single line portion the first touch metal layer and the second touch metal layer are alternately disposed in the single line portion, and another portion of the first touch routing line overlapping with the common electrode comprises a double line portion, the first touch metal layer and the second touch metal layer overlap with each other and the first touch metal layer and the second touch metal layer are electrically connected to each other in the double line portion.
